(19) United States
(12) Patent Application Publication
(10) Pub. No.: US 2026/0122925 A1
(43) Pub. Date: Apr. 30, 2026

(54) SEMICONDUCTOR DEVICES AND METHODS OF FORMATION

(71) Applicant: Taiwan Semiconductor Manufacturing Company, Ltd., Hsinchu (TW)

(72) Inventors: Shen-Hui HONG, Tainan City (TW); Ming-Tsong WANG, Taipei City (TW); Jen-Cheng LIU, Hsin-Chu City (TW)

(21) Appl. No.: 18/930,539

(22) Filed: Oct. 29, 2024

(51) Int. Cl. H01L 23/522; H01L 23/528; H01L 29/66

(52) U.S. Cl. CPC H10D 1/042; H10D 1/047; H10D 1/716; H10W 20/43; H10W 20/496

(57) ABSTRACT

A trench capacitor structure is formed in a semiconductor device to have a deep trench structure that includes a plurality of interconnected trench segments in a top view of the trench capacitor structure. The interconnected trench segments provide a greater amount of surface area along the sidewalls for the electrode layers and insulator layer of the trench capacitor structure, thereby increasing the capacitance of the trench capacitor structure. The interconnected trench segments may be included within a perimeter of the trench capacitor structure so that a compact lateral footprint for the trench capacitor structure may be achieved. Additionally and/or alternatively, the vertical size of the trench capacitor structure (and thus, the capacitance of the trench capacitor structure) may be increased by extending the deep trench structure of the trench capacitor structure fully between bonding structures of the semiconductor device and an underlying device layer of the semiconductor device.

### BACKGROUND

A semiconductor device may include one or more capacitor structures in an interconnect layer (e.g., a back end of line (BEOL) region or back end region) above a device layer. A capacitor structure may perform and/or support one or more functions in the semiconductor device, such as memory (e.g., dynamic random access memory (DRAM)), charge decoupling, analog-to-digital (A/D) conversion, and/or other functions. In some cases, a capacitor structure may be included in a pixel sensor circuit of an image sensor device to provide for overflow photocurrent storage to achieve increased full well capacity for the pixel sensor circuit.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example implementation of a semiconductor device described herein.

FIGS. 2A and 2B are diagrams of an example implementation of a capacitor structure described herein.

FIGS. 3A-3E are diagrams of example implementations of top view layouts for a capacitor structure described herein.

FIGS. 4A-4J are diagrams of an example implementation of forming a semiconductor device described herein.

FIG. 5 is a diagram of another example implementation of a semiconductor device described herein.

FIG. 6 is a diagram of another example implementation of a semiconductor device described herein.

FIGS. 7A-7E are diagrams of an example implementation of forming a semiconductor device described herein.

FIGS. 8A and 8B are diagrams of an example implementation of forming a semiconductor device described herein.

FIGS. 9A and 9B are diagrams of an example implementation of a semiconductor package described herein.

FIGS. 10A and 10B are diagrams of an example implementation of a semiconductor package described herein.

FIG. 11 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A capacitor structure may include a metal-insulator-metal (MIM) structure in which an insulator layer is sandwiched between two conductive electrode layers. The capacitance of the capacitor structure (e.g., the amount of charge that can be stored by the capacitor structure) is directly dependent on the geometry of the conductive electrode layers of the capacitor structure. The greater the surface area of the conductive electrode layers, the greater the capacitance of the capacitor structure. Thus, increasing the size of the metal electrode layers may increase the capacitance of the capacitor structure.

However, increasing a lateral size of the capacitor structure is in direct contention with semiconductor design principles in the semiconductor industry, in which reducing semiconductor device sizes is pursued in order to achieve reduced power consumption, to achieve greater operating performance and efficiencies, and/or to enable semiconductor devices to be used in increasingly smaller form factor applications. Thus, in some cases, the size of a capacitor structure may be increased in a vertical direction in a semiconductor device such that the capacitor structure extends through a plurality of layers in the semiconductor device. A deep trench capacitor (DTC) is a type of capacitor structure that is formed in a deep trench in a semiconductor device such that the electrode layers and insulator layer extend along, and conform to, a profile of the deep trench. This enables the area of the conductive electrode layers to be increased (which increases the capacitance) with minimal increase in the lateral size of the capacitor structure.

In some implementations described herein, a trench capacitor structure (e.g., a DTC structure) is formed in a semiconductor device to have a deep trench structure that includes a plurality of interconnected trench segments in a top view of the trench capacitor structure. The interconnected trench segments provide a greater amount of surface area along the sidewalls for the electrode layers and insulator layer of the trench capacitor structure, thereby increasing the capacitance of the trench capacitor structure. The interconnected trench segments may be included within a perimeter of the trench capacitor structure so that a compact lateral footprint for the trench capacitor structure may be achieved. Additionally and/or alternatively, the vertical size of the trench capacitor structure (and thus, the capacitance of the trench capacitor structure) may be increased by extending the deep trench structure of the trench capacitor structure fully between bonding structures of the semiconductor device and an underlying device layer of the semiconductor device. The bottom of the trench capacitor structure may be electrically connected to a gate structure of an integrated circuit device in the device layer.

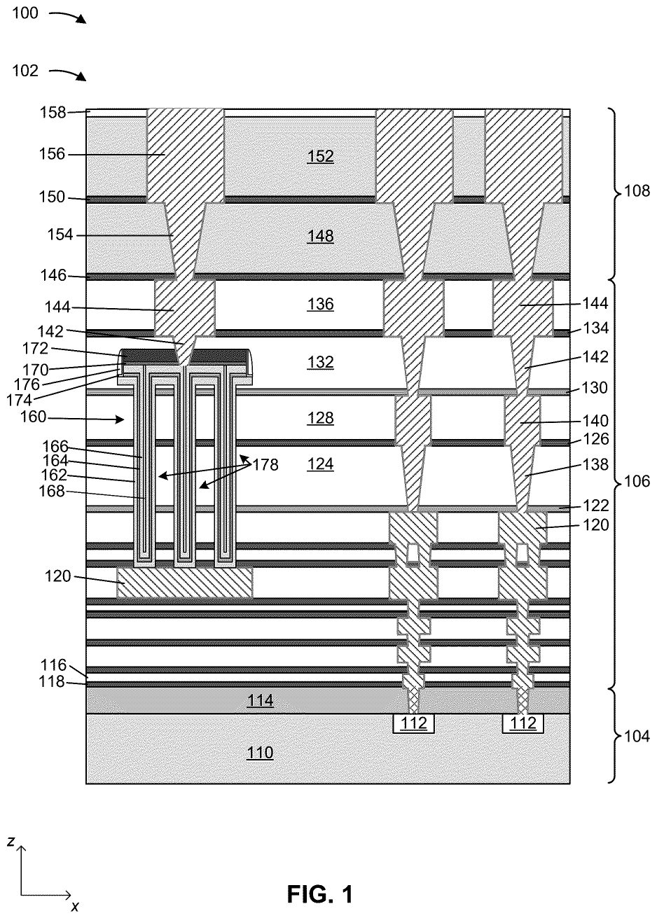

FIG. 1 is a diagram of an example implementation 100 of a semiconductor device 102 described herein. The semiconductor device 102 may include a system on chip (SoC) die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the semiconductor device 102 may include a memory die, an input/output (I/O) die, a pixel sensor die, and/or another type of semiconductor die. A memory die may include a static random access memory (SRAM) die, a DRAM die, a NAND die, a high bandwidth memory (HBM) die, and/or another type of memory die. In general, the semiconductor device 102 is a semiconductor device that includes one or more capacitor structures in an interconnect layer of the semiconductor device 102.

As shown in FIG. 1, the semiconductor device 102 includes a device layer 104, an interconnect layer 106 vertically arranged (e.g., in a z-direction) in the semiconductor device 102 with the device layer 104, and a bonding layer 108 vertically arranged (e.g., in a z-direction) in the semiconductor device 102 with the interconnect layer 106.

The device layer 104 may also be referred to as a frontend region or a front end of line (FEOL) region of the semiconductor device 102. The device layer 104 includes a substrate layer 110. The substrate layer 110 may correspond to a portion of a semiconductor wafer on which the semiconductor device 102 is formed. The substrate layer 110 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate layer 110 may extend in an x-direction and/or in a y-direction in the semiconductor device 102.

Integrated circuit devices 112 may be included in and/or on the substrate layer 110 in the device layer 104 of the semiconductor device 102. The integrated circuit devices 112 may include frontend transistor structures (e.g., frontend planar transistor structures, frontend fin field effect transistor (finFET) structures, frontend gate all around (GAA) transistor structures), pixel sensors, frontend capacitors, frontend resistors, frontend inductors, photodetectors, transceivers, transmitters, receivers, optical circuits, and/or other types of frontend semiconductor devices. “Frontend semiconductor devices” refers to the semiconductor devices that are formed in the device layer 104 (e.g., in and/or on the substrate layer 110) of the semiconductor device 102, as opposed to in the interconnect layer 106 of the semiconductor device 102.

A dielectric layer 114 is included over the substrate layer 110. The dielectric layer 114 includes an interlayer dielectric (ILD) layer, an etch stop layer (ESL), and/or another type of dielectric layer. The dielectric layer 114 includes dielectric material(s) that enable various portions of the substrate layer 110 and/or the integrated circuit devices 112 to be selectively etched or protected from etching, and/or to electrically isolate the integrated circuit devices 112 in the device layer 104. The dielectric layer 114 includes a silicon nitride (SiₓN_{y}), an oxide (e.g., a silicon oxide (SiOₓ) and/or another oxide material), and/or another type of dielectric material. The dielectric layer 114 may extend in the x-direction and/or in a y-direction in the semiconductor device 102.

The interconnect layer 106 of the semiconductor device 102 is included above the substrate layer 110 and above the integrated circuit devices 112 in the z-direction in the semiconductor device 102. The integrated circuit devices 112 may be electrically coupled to the interconnect layer 106. The interconnect layer 106 includes a plurality of dielectric layers (e.g., backend dielectric layers) that are arranged in a direction (e.g., the z-direction) that is approximately perpendicular to the substrate layer 110. The dielectric layers may include ILD layers 116 and ESLs 118 that are arranged in an alternating manner in the z-direction. The ILD layers 116 and the ESLs 118 may extend in the x-direction and/or in the y-direction in the semiconductor device 102.

The ILD layers 116 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 116 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 118 may each include a silicon nitride (SiₓN_{y}), silicon carbide (SiC), silicon oxynitride (SiON), and/or another suitable dielectric material. In some implementations, an ILD layer 116 and an ESL 118 include different dielectric materials to provide etch selectivity to enable various structures to be formed in the interconnect layer 106.

The interconnect layer 106 includes a plurality of conductive structures. One or more of the conductive structures 120 are electrically coupled and/or physically coupled with one or more of the integrated circuit devices 112 in the device layer 104. The conductive structures 120 provide electrical routing that enables signals and/or power to be provided to and/or from the integrated circuit devices 112. The conductive structures 120 may include a combination of metallization structures and interconnect structures. The metallization structures may include trenches, metallization layers, conductive traces, and/or other types of metallization structures.

The interconnect structures may include vias, plugs, interconnects, and/or another type of interconnect structures. The conductive structures 120 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included on the conductive structures 120. The one or more liner layers may include barrier liners, adhesion liners, and/or another type of liners. Examples of materials for the one or more liners include tantalum nitride (TaN) and/or titanium nitride (TiN), among other examples.

In some implementations, the conductive structures 120 may be arranged in a plurality of layers that are arranged in a vertical manner (e.g., in the z-direction) in the interconnect layer 106. In other words, a plurality of layers of conductive structures 120 may extend above the device layer 104 in the interconnect layer 106 to facilitate electrical signals and/or power to be routed between the device layer 104 and the interconnect layer 106. The metallization structures may be arranged in metallization layers referred to as M-layers. For example, a metal-0 (M0) layer that includes a plurality of conductive structures 120 (e.g., metallization structures) may be located at the bottom of the interconnect layer 106 and may be directly coupled with the device layer 104 (e.g., with the integrated circuit devices 112 in the device layer 104). A via-1 (V1) layer that includes a plurality of conductive structures (e.g., interconnect structures) may be included above the M0 layer. A metal-1 layer (M1) layer that includes a plurality of conductive structures 120 (e.g., metallization structures) may be located above the V1 layer in the interconnect layer 106, a via-2 (V2) layer that includes a plurality of conductive structures (e.g., interconnect structures) may be included above the M1 layer, a metal-2 layer (M2) layer that includes a plurality of conductive structures 120 (e.g., metallization structures) may be located above the V2 layer, and so on.

One or more top metal layers may be included above the conductive structures 120 (e.g., the M-layers and the V-layers) in the interconnect layer 106. For example, the interconnect layer 106 may include an ESL 122, an ILD layer 124, an ESL 126, an ILD layer 128, an ESL 130, an ILD layer 132, an ESL 134, and an ILD layer 136, and may include a top via 138 (e.g., extending through the ESL 122 and the ILD layer 124), a top metal layer 140 (e.g., extending through the ESL 126 and the ILD layer 128), a top via 142 (e.g., extending through the ESL 130 and the ILD layer 132), and/or a top metal layer 144 (e.g., extending through the ESL 134 and/or the ILD layer 136), among other examples.

The top vias 138 and 142 may be physically larger (e.g., may be taller in the z-direction) than the interconnect structures of the conductive structures 120. Similarly, the top metal layers 140 and 144 may be physically larger (e.g., may be taller in the z-direction) than the metallization structures of the conductive structures 120. For example, the metallization structures of the conductive structures 120 may have sub-micron z-direction heights, whereas the top metal layers 140 and 144 may have z-direction heights of approximately 1 micron or greater. However, other z-direction heights for the metallization structures of the conductive structures 120 and for the top metal layers 140 and 144 are within the scope of the present disclosure.

The physically larger sizes of the top vias 138 and 142 and of the top metal layers 140 and 144 provide for lower sheet resistance and enable higher current signals to be handled at the top of the interconnect layer 106. The physically smaller sizes of the conductive structures 120 enable a higher density of conductive structures 120 to be included closer to the integrated circuit devices 112 in the device layer 104, which enables the integrated circuit devices 112 to be positioned closer together for higher integrated circuit device density in the device layer 104.

In some implementations, the ESLs 122, 126, 130, and 134 may include an alternating arrangement of materials. For example, the ESLs 122 and 130 may include silicon carbide (SiC), and the ESLs 126 and 134 may include a silicon nitride (SiₓN_{y} such as Si₃N₄). However, other combinations of materials for the ESLs 122, 126, 130, and 134 are within the scope of the present disclosure.

In some implementations, the ESL 122 may have a z-direction thickness that is included in a range of approximately 300 angstroms to approximately 800 angstroms. However, other values for the range are within the scope of the present disclosure. In some implementations, the ILD layer 124 may have a z-direction thickness that is included in a range of approximately 4000 angstroms to approximately 8000 angstroms. However, other values for the range are within the scope of the present disclosure. In some implementations, the ESL 126 may have a z-direction thickness that is included in a range of approximately 300 angstroms to approximately 700 angstroms. However, other values for the range are within the scope of the present disclosure. In some implementations, the ILD layer 128 may have a z-direction thickness that is included in a range of approximately 6000 angstroms to approximately 12000 angstroms. However, other values for the range are within the scope of the present disclosure. In some implementations, the ESL 130 may have a z-direction thickness that is included in a range of approximately 300 angstroms to approximately 800 angstroms. However, other values for the range are within the scope of the present disclosure. In some implementations, the ILD layer 132 may have a z-direction thickness that is included in a range of approximately 4000 angstroms to approximately 8000 angstroms. However, other values for the range are within the scope of the present disclosure. In some implementations, the ESL 134 may have a z-direction thickness that is included in a range of approximately 300 angstroms to approximately 700 angstroms. However, other values for the range are within the scope of the present disclosure. In some implementations, the ILD layer 136 may have a z-direction thickness that is included in a range of approximately 7000 angstroms to approximately 10000 angstroms. However, other values for the range are within the scope of the present disclosure.

The bonding layer 108 may be connected to the top metal layer 144 of the interconnect layer 106. The bonding layer 108 may include additional ESLs and dielectric layers, such as an ESL 146, a dielectric layer 148, an ESL 150, and/or a dielectric layer 152, among other examples. Moreover, the bonding layer 108 may include bonding vias 154 (e.g., that extend through the ESL 146 and/or the dielectric layer 148) and bonding pads 156 (e.g., that extend through the ESL 150 and/or the dielectric layer 152). The bonding vias 154 may be electrically connected and/or physically connected to the top metal layer 144, and the bonding pads 156 may be electrically connected and/or physically connected to the bonding vias 154.

The ESLs 146 and 150 may each include a silicon nitride (SiₓN_{y}), silicon carbide (SiC), silicon oxynitride (SiON), and/or another suitable dielectric material. The dielectric layers 148 and 152 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material.

In some implementations, the ESL 146 may have a z-direction thickness that is included in a range of approximately 500 angstroms to approximately 1000 angstroms. However, other values for the range are within the scope of the present disclosure. In some implementations, the dielectric layer 148 may have a z-direction thickness that is included in a range of approximately 4000 angstroms to approximately 9000 angstroms. However, other values for the range are within the scope of the present disclosure. In some implementations, the ESL 150 may have a z-direction thickness that is included in a range of approximately 800 angstroms to approximately 1600 angstroms. However, other values for the range are within the scope of the present disclosure. In some implementations, the dielectric layer 152 may have a z-direction thickness that is included in a range of approximately 6000 angstroms to approximately 12000 angstroms. However, other values for the range are within the scope of the present disclosure.

The bonding vias 154 include conductive structures that are elongated primarily in the z-direction. The bonding vias 154 may electrically couple the top metal layer 144 to the bonding pads 156. The bonding pads 156 include electrically conductive pads that are used for bonding the semiconductor device 102 to another semiconductor device to form a vertically stacked semiconductor package. The bonding vias 154 and bonding pads 156 include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The bonding layer 108 further includes a bonding dielectric layer 158 around the bonding pads 156. The bonding dielectric layer 158 may also be used to bond the semiconductor device 102 to another semiconductor device to form a vertically stacked semiconductor package. Thus, the combination of the bonding pads 156 and the bonding dielectric layer 158 enables the semiconductor device 102 to be bonded to another semiconductor device in a metal-to-metal bond and in a dielectric-to-dielectric bond. The bonding dielectric layer 158 may include one or more dielectric materials such as a silicon nitride (SiₓN_{y}), silicon carbide (SiC), silicon oxynitride (SiON), and/or another suitable dielectric material. In some implementations, a z-direction thickness of the bonding dielectric layer 158 may be included in a range of approximately 500 angstroms to approximately 1000 angstroms. However, other values for the range are within the scope of the present disclosure.

As further shown in FIG. 1, the semiconductor device 102 may include one or more capacitor structures 160. A capacitor structure 160 may include a trench capacitor structure that is included in and extends through a portion of the bonding layer 108, and is included in and extends through a portion of the interconnect layer 106. The capacitor structure 160 may include a DTC structure in that the capacitor structure 160 has a high aspect ratio between a vertical (z-direction) height of the capacitor structure 160 and a lateral (x-direction) width of the capacitor structure 160. For example, the aspect ratio of the capacitor structure 160 may be greater than approximately 10:1, and in some implementations is included in a range of approximately 18:1 to approximately 55:1. However, other values and ranges for the aspect ratio for the capacitor structure 160 are within the scope of the present disclosure.

As shown in FIG. 1, the capacitor structure 160 includes a plurality of conformal layers, including a bottom electrode layer 162, an insulator layer 164 on the bottom electrode layer 162, and a top electrode layer 166 on the insulator layer 164. Thus, the insulator layer 164 is located between the bottom electrode layer 162 and the top electrode layer 166, which enables the capacitor structure 160 to store an electrical charge based on the capacitance between the bottom electrode layer 162 and the top electrode layer 166. A dielectric filler 168 may be included between segments of the top electrode layer 166 to electrically isolate the segments of the top electrode layer 166. However, in other implementations, the dielectric filler 168 is omitted.

The bottom electrode layer 162, the insulator layer 164, and the top electrode layer 166 correspond to an MIM stack of the capacitor structure 160. Thus, the capacitor structure 160 may also be referred to as an MIM capacitor structure. The bottom electrode layer 162 (also referred to as a capacitor bottom metal (CBM)) and the top electrode layer 166 (also referred to as a capacitor top metal (CTM)) may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), tantalum (Ta), aluminum (Al), copper (Cu), gold (Au), titanium nitride (TiN), and/or tantalum nitride (TaN), among other examples. In some implementations, the bottom electrode layer 162 and the top electrode layer 166 include the same material or the same material composition. In some implementations, the bottom electrode layer 162 and the top electrode layer 166 include different materials or different material compositions.

The insulator layer 164 may include one or more electrically insulating materials. In some implementations, the insulator layer 164 includes one or more low-k dielectric materials such as silicon oxide (SiOₓ such as SiO₂). Additionally and/or alternatively, the insulator layer 164 may include one or more high-k dielectric materials such as zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), and/or hafnium oxide (HfOₓ such as HfO₂), among other examples. In some implementations, the insulator layer 164 is a multiple-layer stack that includes a plurality of dielectric layers. For example, the insulator layer 164 may include a ZrO₂/Al₂O₃/ZrO₂ (ZAZ) layer stack.

As further shown in FIG. 1, the capacitor structure 160 may include one or more capping layers above the top electrode layer 166. The one or more capping layers may include a capping layer 170, a capping layer 172, and/or another capping layer. The capping layers may provide electrical isolation for the MIM stack of the capacitor structure 160, and/or may also function as a hard mask layer stack for etching the bottom electrode layer 162, the insulator layer 164, and/or the top electrode layer 166. The capping layers 170 and 172 may include an oxide-containing dielectric material such as silicon oxide (SiOₓ such as SiO₂), an oxynitride-containing dielectric material such as silicon oxynitride (SiON), a nitride-containing dielectric material such as silicon nitride (SiₓN_{y} such as Si₃N₄), and/or another suitable dielectric material. In some implementations, the capping layers 170 and 172 include the same material and/or the same material composition. In some implementations, the capping layers 170 and 172 include different materials and/or different material compositions.

As further shown in FIG. 1, the capacitor structure 160 may include one or more sidewall spacers 174 and/or 146 on the sidewalls of the capping layers 170 and/or 172, and/or on sidewalls of the top electrode layer 166 at the top of the capacitor structure 160. The combination of the capping layers 170, 172 and the sidewall spacers 174, 176 may be used as a self-aligned mask when etching a layer to define the bottom electrode layer 162. The sidewall spacer 174 may include an oxide-containing dielectric material such as silicon oxide (SiOₓ such as SiO₂), among other examples. The sidewall spacer 176 may include a nitride-containing dielectric material such as silicon nitride (SiₓN_{y} such as Si₃N₄), among other examples.

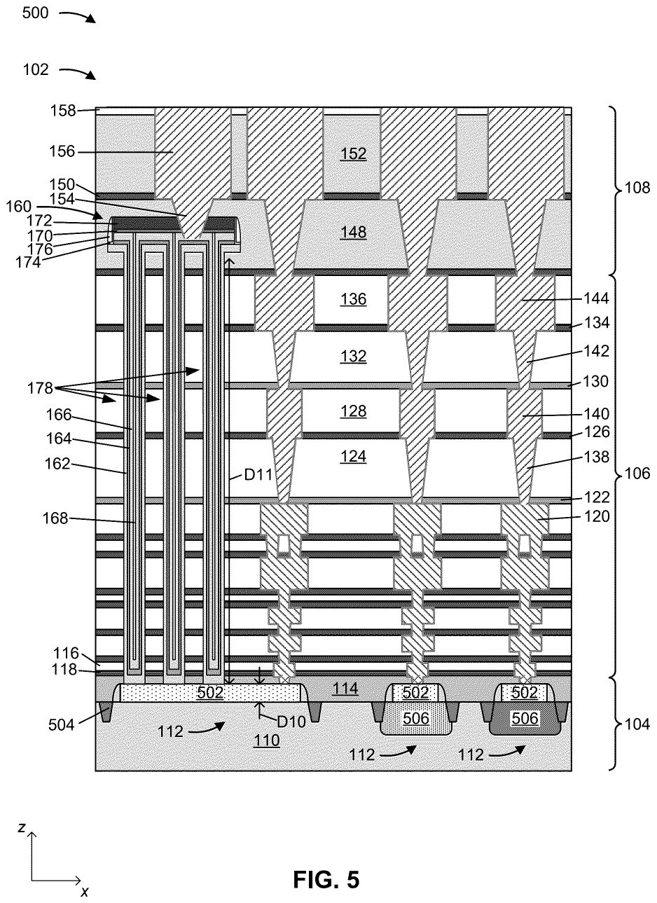

As further shown in FIG. 1, the capacitor structure 160 may include a deep trench structure 178 that vertically extends (e.g., in the z-direction) through a plurality of dielectric layers in the interconnect layer 106. For example, the deep trench structure 178 may extend through one or more ILD layers 116, one or more ESLs 118, the ESL 122, the ILD layer 124, the ESL 126, the ILD layer 128, the ESL 130, and/or the ILD layer 132, among other examples. In the example illustrated in FIG. 1, the top of the capacitor structure 160 (e.g., the top electrode layer 166) is physically coupled and/or electrically coupled to a top via 142 in the interconnect layer 106. In other examples, such as illustrated in examples in FIGS. 5, 6, 9A, 9B, 10A, and 10B, the top of the capacitor structure 160 (e.g., the top electrode layer 166) may be physically coupled and/or electrically coupled to a bonding via 154 or a bonding pad 156. In these examples, the deep trench structure 178 of the capacitor structure 160 may also extend into and/or through the ESL 134, the ILD layer 136, the ESL 146, the dielectric layer 148, the ESL 150, and/or the dielectric layer 152, among other examples. In some implementations, the deep trench structure 178 may have a z-direction depth (or height) that is included in a range of approximately 0.25 microns to approximately 6 microns. However, other values and ranges are within the scope of the present disclosure.

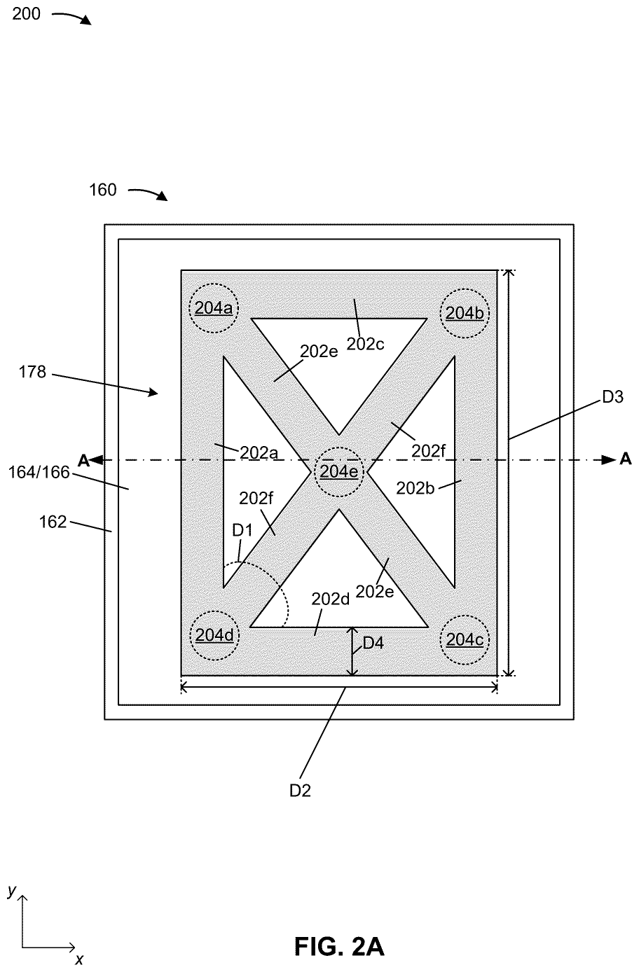

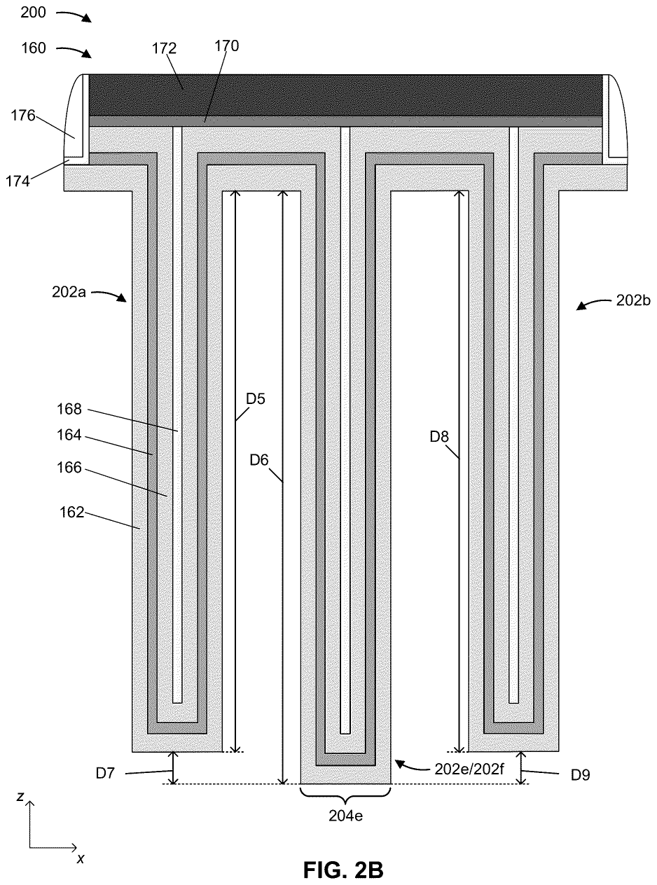

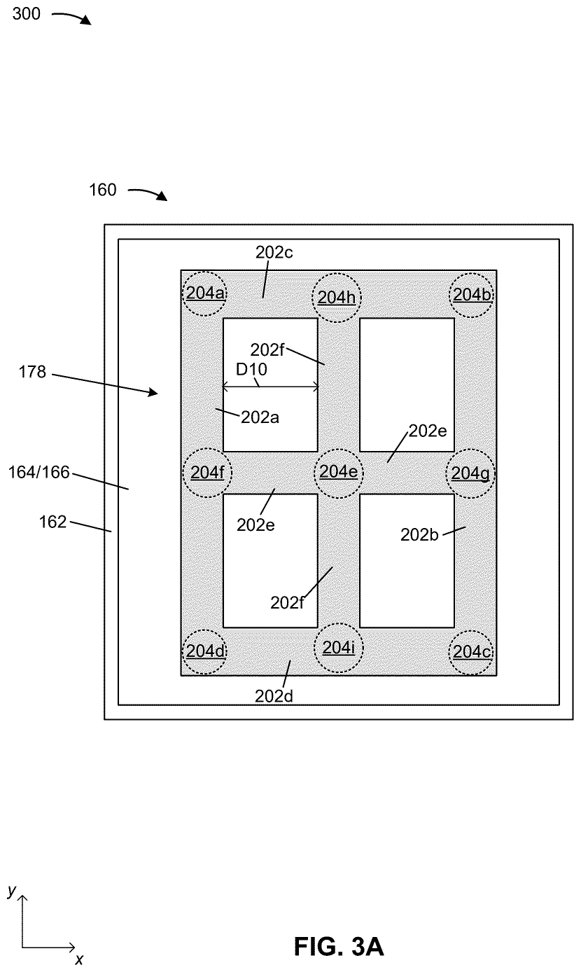

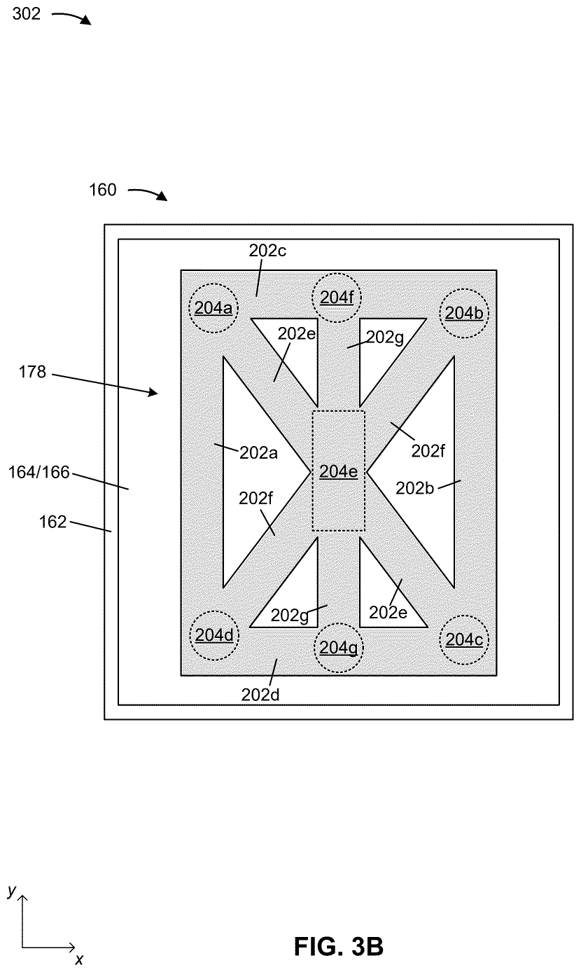

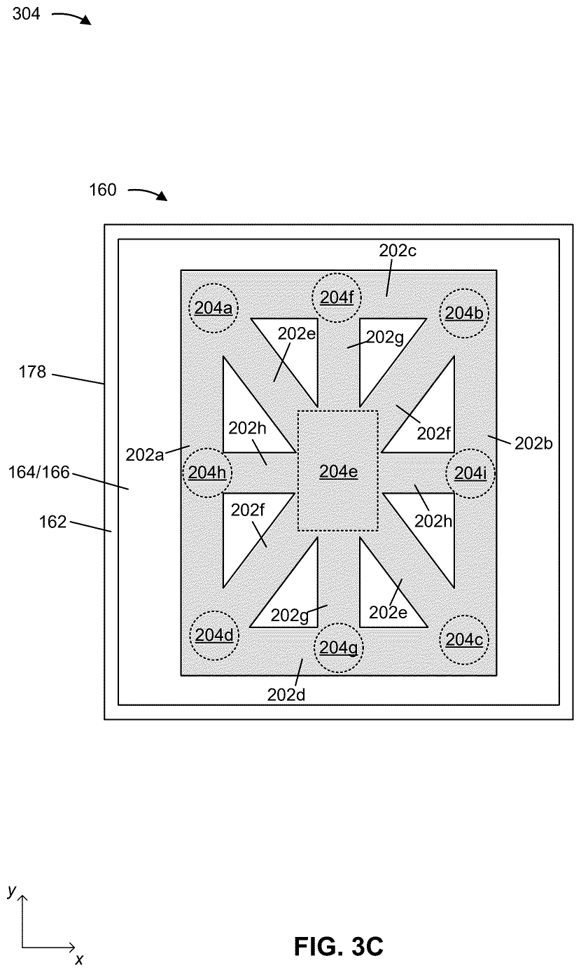

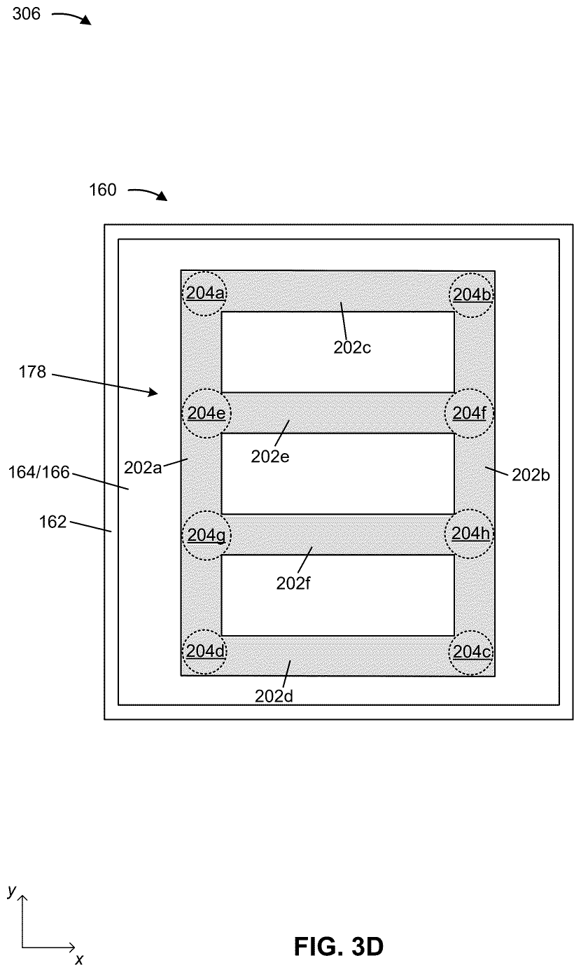

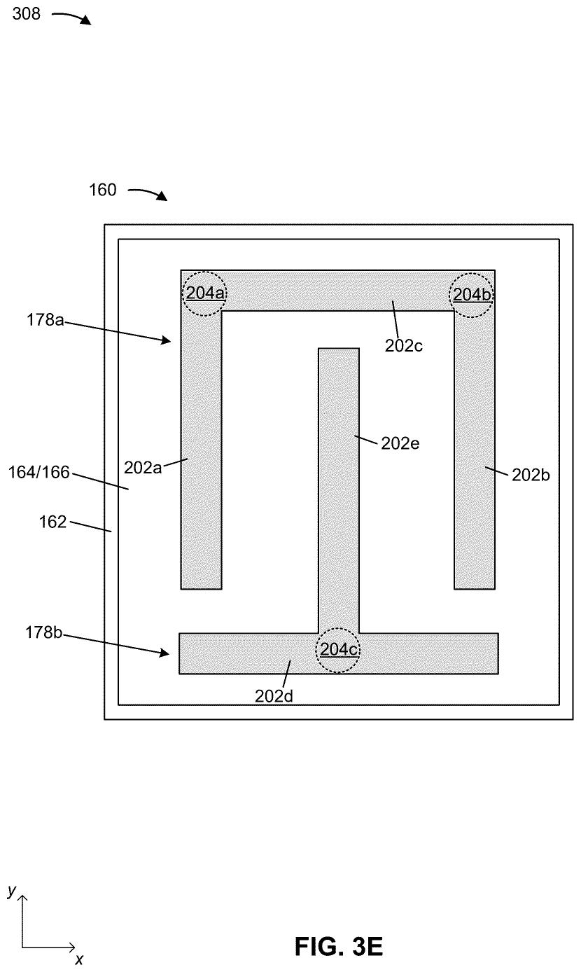

FIGS. 2A and 3A-3E illustrate various examples of top view layouts for trench segments of the deep trench structure 178. As described in connection with FIGS. 2A and 3A-3E, the trench segments of the deep trench structure 178 may be interconnected and may provide increased surface area for the bottom electrode layer 162, the insulator layer 164, and the top electrode layer 166 (e.g., as opposed to having only non-connected trenches arranged in the top view of the capacitor structure 160), which enables increased capacitance to be achieved for the capacitor structure.

As further shown in FIG. 1, the bottom electrode layer 162, the insulator layer 164, and/or the top electrode layer 166 may be conformal layers that extend into the deep trench structure 178. In particular, the bottom electrode layer 162, the insulator layer 164, and/or the top electrode layer 166 may extend along the sidewalls and the bottom surfaces of the deep trench structure 178. The portions of the bottom electrode layer 162 at the bottom of the capacitor structure 160 may be on, and in physical contact with, an underlying conductive structure 120 at the bottom of the capacitor structure 160. Thus, the bottom electrode layer 162 may be electrically connected to the conductive structure 120 in the interconnect layer 106.

As indicated above, FIG. 1 is provided as an example. Other examples may differ from what is described with regard to FIG. 1.

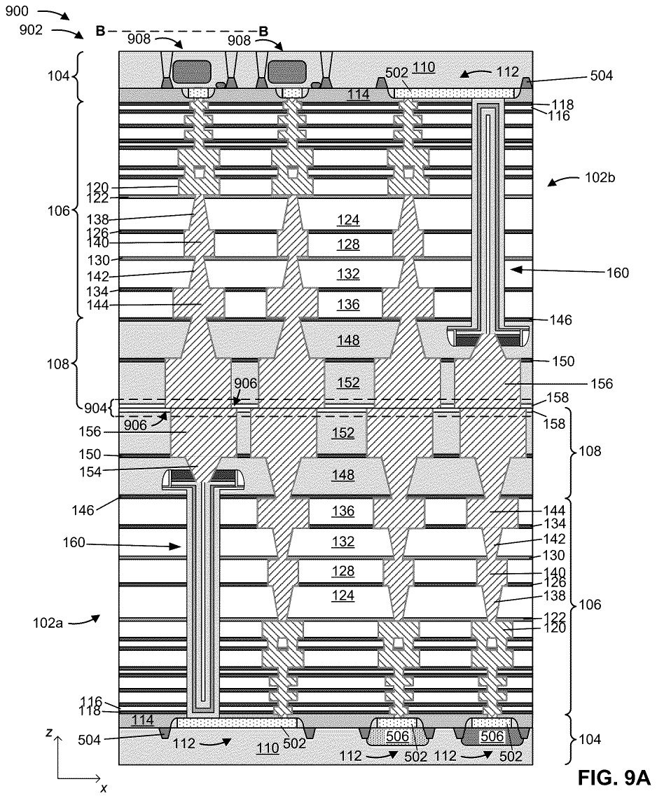

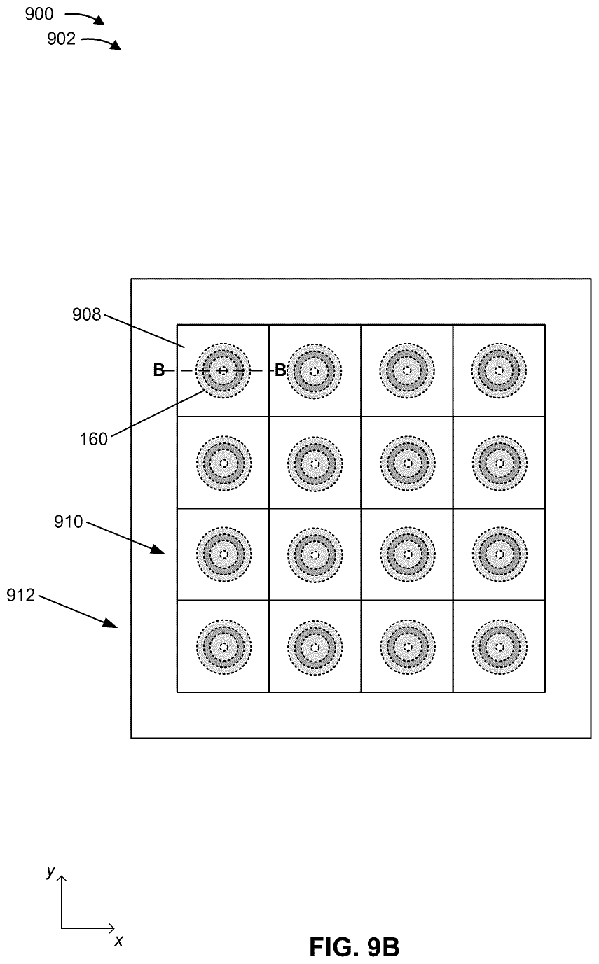

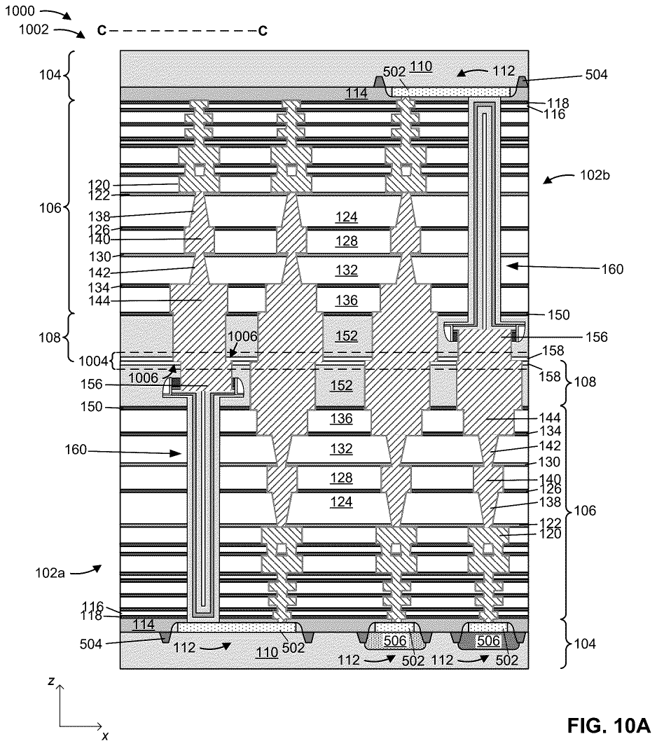

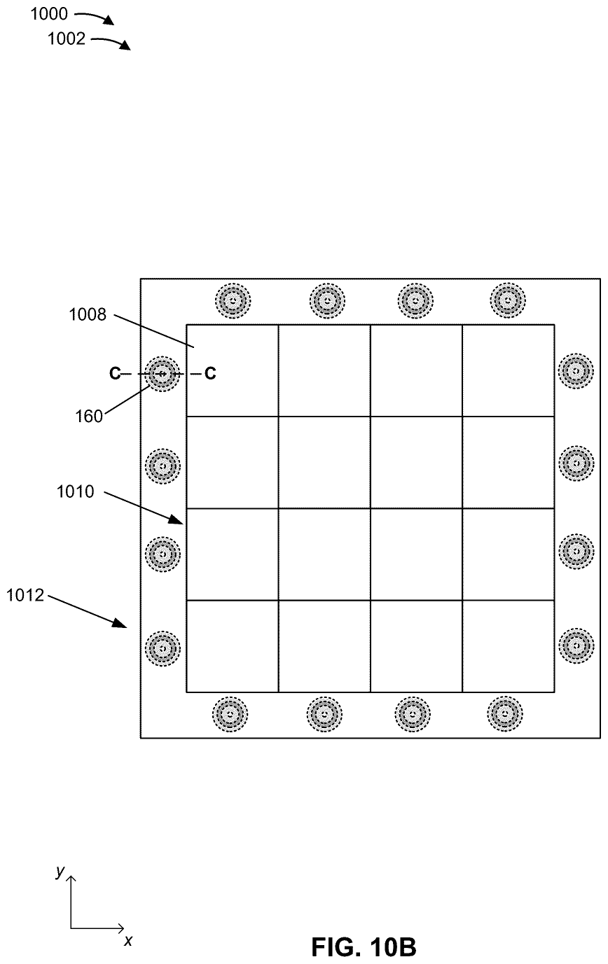

FIGS. 2A and 2B are diagrams of an example implementation 200 of a capacitor structure 160 described herein. The capacitor structure 160 may be included in the interconnect layer 106 of the semiconductor device 102, and/or may be included in an interconnect layer 106 of another semiconductor device described herein, such as a semiconductor device 102a illustrated in FIG. 9A and/or in FIG. 10A, a semiconductor device 102b illustrated in FIG. 9A and/or in FIG. 10A, and/or another semiconductor device.

FIG. 2A illustrates a top view layout of the capacitor structure 160 in an x-y plane. As shown in the top view layout of the capacitor structure 160 in FIG. 2A, the deep trench structure 178 of the capacitor structure 160 includes a plurality of interconnected trench segments 202a-202f. The trench segments 202a, 202b, 202c, and 202d, may be connected in a closed-loop arrangement and may define the perimeter of the deep trench structure 178. The trench segments 202e and 202f may extend within the perimeter of the deep trench structure 178 and may be connected to one or more of the trench segments 202a, 202b, 202c, and/or 202d. The bottom electrode layer 162, the insulator layer 164, and the top electrode layer 166 may extend into (e.g., along the sidewalls and the bottom surface of) the trench segments 202a-202f.

Two or more of the trench segments 202a-202f may be connected in various connection regions of the deep trench structure 178. “Connection region” refers to a region of the deep trench structure 178 where two or more trench segments connect. A connection region may be located at ends of two or more trench segments, may be located at a center point or midpoint along a first trench segment and an end of a second trench segment, may be located at center points or midpoints along two or more trench segments, and/or may be located at other locations along two or more trench segments.

As shown in the example top view layout in FIG. 2A, a first end of the trench segment 202a and a first end of the trench segment 202c may be connected at a connection region 204a of the deep trench structure 178. A first end of the trench segment 202b and a second end of the trench segment 202c (e.g., opposing the first end of the trench segment 202c) may be connected at a connection region 204b of the deep trench structure 178. A second end of the trench segment 202b (e.g., opposing the first end of the trench segment 202b) and a second end of the trench segment 202d (e.g., opposing the first end of the trench segment 202d) may be connected at a connection region 204c of the deep trench structure 178. A second end of the trench segment 202a (e.g., opposing the first end of the trench segment 202a) and a first end of the trench segment 202d may be connected at a connection region 204d of the deep trench structure 178.

As further shown in the example top view layout in FIG. 2A, a first end of the trench segment 202e may be connected to the first end of the trench segment 202a and to the first end of the trench segment 202c in the connection region 204a. A second end of the trench segment 202e (e.g., opposing the first end of the trench segment 202e) may be connected to the second end of the trench segment 202b and the second end of the trench segment 202d in the connection region 204c. A first end of the trench segment 202f may be connected to the first end of the trench segment 202b and to the second end of the trench segment 202c in the connection region 204b. A second end of the trench segment 202f (e.g., opposing the first end of the trench segment 202f) may be connected to the second end of the trench segment 202a and to the first end of the trench segment 202d in the connection region 204d. The trench segments 202e and 202f may be connected (e.g., at approximate midpoints along the trench segments 202e and 202f) at a connection region 204e. The connection regions 204a-204d may be located at corners of the perimeter of the deep trench structure 178, whereas the connection region 204e may be located at an approximate center of the deep trench structure 178.

In some implementations, the trench segments 202a, 202b, 202c, and 202d may be arranged in an approximate hollow square layout in the top view of the capacitor structure 160 or in an approximate hollow rectangle layout in the view of the capacitor structure 160. The trench segments 202e and 202f, in the example top view layout in FIG. 2A, may extend diagonally through the interior of the perimeter of the deep trench structure 178. In these implementations, an angle between the trench segments 202a and 202c, an angle between the trench segments 202b and 202c, an angle between the trench segments 202b and 202d, and an angle between the trench segments 202a and 202d may each be included in a range of approximately 85 degrees to approximately 95 degrees. However, other values and ranges are within the scope of the present disclosure. In some implementations, the trench segments 202a, 202b, 202c, and 202d may be arranged in another hollow top view layout.

The perimeter of the deep trench structure 178 may have an x-direction width (dimension D2) and a y-direction width (dimension D3). In some implementations, the x-direction width and the y-direction width may each be included in a range of approximately 0.5 microns to approximately 10 microns. If the x-direction width and/or the y-direction width is less than approximately 0.5 microns, insufficient spacing may be provided between the trench segments 202a-202f, resulting in reduced surface area for the bottom electrode layer 162, the insulator layer 164, and the top electrode layer 166 (and thus, reduced capacitance for the capacitor structure 160). If the x-direction width and/or the y-direction width is greater than approximately 10 microns, the lateral footprint of the deep trench structure 178 may be too large, resulting in reduced density of structures and/or devices in the interconnect layer 106 of the semiconductor device 102. However, other values, and ranges other than approximately 0.5 microns to approximately 10 microns, are within the scope of the present disclosure.

In some implementations, the lateral widths of each of the trench segments 202a-202f (dimension D4) may be included in a range of approximately 0.1 microns to approximately 1 micron. If the lateral width of a trench segment 202a-202f is less than approximately 0.1 microns, insufficient gap-filling performance may result when forming the deep trench structure 178, which may result in the formation of voids and other discontinuities in the bottom electrode layer 162, in the insulator layer 164, and/or in the top electrode layer 166. If the lateral width of a trench segment 202a-202f is greater than approximately 1 micron, insufficient spacing may be provided between the trench segments 202a-202f, resulting in reduced surface area for the bottom electrode layer 162, the insulator layer 164, and the top electrode layer 166 (and thus, reduced capacitance for the capacitor structure 160). However, other values, and ranges other than approximately 0.1 microns to approximately 1 micron, are within the scope of the present disclosure.

FIG. 2B illustrates a cross-section view of the capacitor structure 160 along the line A-A in FIG. 2A. Thus, the cross-section view of the capacitor structure 160 in FIG. 2B includes a portion of the trench segment 202a (e.g., in a non-connection region), a portion of the trench segment 202b (e.g., in a non-connection region), and portions of the trench segments 202e and 202f (e.g., in the connection region 204e).

The portions of the trench segments in the connection regions of the deep trench structure 178 may have a greater depth or z-direction height than the portions of the trench segments that are not located in the connection regions. For example, and as shown in FIG. 2B, the portion of the trench segment 202a in a non-connection region may have a z-direction depth (e.g., between a top of the trench segment 202a and a bottom of the trench segment 202a) indicated in FIG. 2B as dimension D5, the portions of the trench segments 202e and 202f (e.g., in the connection region 204e) may have a z-direction depth (e.g., between tops of the trench segments 202e and 202f and bottoms of the trench segments 202e and 202f) indicated in FIG. 2B as dimension D6, and the dimension D6 may be greater than the dimension D5 by a difference indicated in FIG. 2B as a dimension D7. As another example, and as shown in FIG. 2B, the portion of the trench segment 202b in a non-connection region may have a z-direction depth (e.g., between a top of the trench segment 202b and a bottom of the trench segment 202b) indicated in FIG. 2B as dimension D8, and the dimension D6 may be greater than the dimension D8 by a difference indicated in FIG. 2B as a dimension D9.

The differences in z-direction depths or heights of the non-connection regions and the connection regions 204a-204e may be due to depth loading that occurs in the connection regions 204a-204e when forming the deep trench structure 178. For example, the dielectric layers in which the deep trench structure 178 is formed may be etched using an etchant, and the etchant may remove material from the dielectric layers faster in the connection regions 204a-204e than in the non-connection regions of the deep trench structure 178 because of the larger open volume in the connection regions 204a-204e. The larger open volume (meaning the larger open area of the recesses formed for the deep trench structure 178 in the connection regions 204a-204e) results in a greater amount of etchant being in contact with the dielectric layers for a longer duration, thereby resulting in a greater amount of etching. As indicated above, FIGS. 2A and 2B are provided as an example. Other examples may differ from what is described with regard to FIGS. 2A and 2B.

FIGS. 3A-3E are diagrams of example implementations of top view layouts for a capacitor structure 160 described herein. The example implementations of top view layouts illustrated in FIGS. 3A-3E are non-limiting examples, and other example implementations of top view layouts for a capacitor structure 160 described herein are within the scope of the present disclosure.

FIG. 3A illustrates an example implementation 300 of a top view layout for a capacitor structure 160. As shown in FIG. 3A, the example implementation 300 of the top view layout is similar to the top view layout in the example implementation 200 in FIG. 2A. For example, in the example implementation 300 of the top view layout, the deep trench structure 178 of the capacitor structure 160 includes trench segments 202a-202f and connection regions 204a-204e similar to the top view layout in the example implementation 200 in FIG. 2A.

However, in the example implementation 300 of the top view layout, the trench segments 202e and 202f extend approximately perpendicular to each other (e.g., as opposed to diagonally) and connect to the trench segments 202a-202d at connection regions 204f-204i that are not located at the ends of the trench segments 202a-202d. For example, the first end of the trench segment 202e may be connected to an approximate midpoint along the trench segment 202a in a connection region 204f, and the second end of the trench segment 202e may be connected to an approximate midpoint along the trench segment 202b in a connection region 204g. As another example, the first end of the trench segment 202f may be connected to an approximate midpoint along the trench segment 202c in a connection region 204h, and the second end of the trench segment 202f may be connected to an approximate midpoint along the trench segment 202d in a connection region 204i.

Thus, the trench segments 202e and 202f form a cross shape or (plus (+) shape) in the top view of the deep trench structure 178 of the capacitor structure 160, as opposed to an X shape. The trench segment 202e extends approximately parallel to the trench segments 202c and 202d in the x-direction, and the trench segment 202f extends approximately parallel to the trench segments 202a and 202b in the y-direction.

As further shown in FIG. 2B, a dimension D10 may correspond to a distance or spacing between trench segments, such as between the trench segments 202a and 202f. In some implementations, a minimum spacing between trench segments may be included in a range of approximately 0.10 microns to approximately 0.2 microns. However, other values and ranges are within the scope of the present disclosure. In some implementations, a quantity of trench segments may be included in a range of 2 to 20. In some implementations, a quantity of trench segments may be greater than 20. Moreover, other quantities of trench segments are within the scope of the present disclosure.

FIG. 3B illustrates an example implementation 302 of a top view layout for a capacitor structure 160. As shown in FIG. 3B, the example implementation 302 of the top view layout is similar to the top view layout in the example implementation 200 in FIG. 2A. For example, in the example implementation 302 of the top view layout, the deep trench structure 178 of the capacitor structure 160 includes trench segments 202a-202f and connection regions 204a-204e similar to the top view layout in the example implementation 200 in FIG. 2A. Moreover, the trench segments 202e and 202f extend diagonally within a perimeter of the deep trench structure 178 and are connected to trench segments 202a-202d in the connection regions 204a-204d at the corners of the deep trench structure 178.

However, in the example implementation 302 of the top view layout, the deep trench structure 178 of the capacitor structure 160 includes an additional trench segment 202g that extends approximately parallel to the trench segments 202a and 202b. The trench segment 202g extends through the approximate center of the deep trench structure 178 (e.g., in the y-direction as shown in FIG. 3B, or alternatively in the x-direction) and intersects with the trench segments 202e and 202f in the connection region 204e. A first end of the trench segment 202g may be connected to an approximate midpoint along the trench segment 202c in a connection region 204f, and a second end of the trench segment 202g (e.g., opposing the first end of the trench segment 202g) may be connected to an approximate midpoint along the trench segment 202d in a connection region 204g.

The additional trench segment 202g may provide additional surface area for the bottom electrode layer 162, for the insulator layer 164, and/or for the top electrode layer 166, thereby further increasing the capacitance of the capacitor structure 160.

FIG. 3C illustrates an example implementation 304 of a top view layout for a capacitor structure 160. As shown in FIG. 3C, the example implementation 304 of the top view layout is similar to the top view layout in the example implementation 302 in FIG. 3B. For example, in the example implementation 304 of the top view layout, the deep trench structure 178 of the capacitor structure 160 includes trench segments 202a-202g and connection regions 204a-204g similar to the top view layout in the example implementation 302 in FIG. 3B.

However, in the example implementation 304 of the top view layout, the deep trench structure 178 of the capacitor structure 160 includes an additional trench segment 202h that extends approximately parallel to the trench segments 202c and 202d. The trench segment 202h extends through the approximate center of the deep trench structure 178 (e.g., in the x-direction as shown in FIG. 3B, or alternatively in the x-direction) and intersects with the trench segments 202e, 202f, and 202g in the connection region 204e. A first end of the trench segment 202h may be connected to an approximate midpoint along the trench segment 202a in a connection region 204h, and a second end of the trench segment 202h (e.g., opposing the first end of the trench segment 202h) may be connected to an approximate midpoint along the trench segment 202b in a connection region 204i.

The additional trench segment 202h may provide additional surface area for the bottom electrode layer 162, for the insulator layer 164, and/or for the top electrode layer 166, thereby further increasing the capacitance of the capacitor structure 160.

FIG. 3D illustrates an example implementation 306 of a top view layout for a capacitor structure 160. As shown in FIG. 3D, the example implementation 306 of the top view layout is similar to the top view layout in the example implementation 200 in FIG. 2A. For example, in the example implementation 306 of the top view layout, the deep trench structure 178 of the capacitor structure 160 includes trench segments 202a-202f and connection regions 204a-204d similar to the top view layout in the example implementation 200 in FIG. 2A.

However, in the example implementation 306 of the top view layout, the trench segments 202e and 202f extend approximately parallel to each other (e.g., as opposed to diagonally). Thus, the trench segments 202e and 202f do not intersect and instead are spaced apart from each other. The trench segments 202e and 202f extend approximately parallel to the trench segments 202c and 202d (and to each other) in the x-direction.

The trench segments 202e and 202f connect to the trench segments 202a-202d at connection regions 204e-204h that are not located at the ends of the trench segments 202a-202d. For example, the first end of the trench segment 202e may be connected to the trench segment 202a in a connection region 204e that is located between the ends of the trench segment 202a, and the second end of the trench segment 202e may be connected to the trench segment 202b in a connection region 204f that is located between the ends of the trench segment 202b. As another example, the first end of the trench segment 202f may be connected to the trench segment 202a in a connection region 204g that is located between the ends of the trench segment 202a, and the second end of the trench segment 202f may be connected to the trench segment 202b in a connection region 204h that is located between the ends of the trench segment 202b. The connection regions 204e and 204g may be non-overlapping so that the trench segments 202e and 202f do not contact each other, and the connection regions 204f and 204h may be non-overlapping so that the trench segments 202e and 202f do not contact each other.

FIG. 3E illustrates an example implementation 308 of a top view layout for a capacitor structure 160. As shown in FIG. 3E, in example implementation 308 of the top view layout, a capacitor structure 160 includes a plurality of non-contiguous deep trench structures 178. While two deep trench structures 178 (e.g., a deep trench structure 178a and a deep trench structure 178b) are illustrated in the example in FIG. 3E, other quantities of deep trench structures for capacitor structures 160 described herein are within the scope of the present disclosure.

As further shown in FIG. 3E, each of the deep trench structures 178a and 178b includes a plurality of trench segments. For example, the deep trench structure 178a includes trench segments 202a-202c, and the deep trench structure 178b includes trench segments 202d and 202d. These arrangements are examples, and other examples of trench segment arrangements and quantities are within the scope of the present disclosure.

In the deep trench structure 178a, a first end of the trench segment 202a and a first end of the trench segment 202c may be connected in a connection region 204a. A second end of the trench segment 202a may be facing the deep trench structure 178b. A first end of the trench segment 202b and a second end of the trench segment 202c may be connected in a connection region 204b. A second end of the trench segment 202b may be facing the deep trench structure 178b. The trench segments 202a-202c and the connection regions 204a and 204b may be arranged such that the deep trench structure 178a has an approximately U-shaped top view layout. However, other top view layouts for the deep trench structure 178a are within the scope of the present disclosure.

In the deep trench structure 178b, a first end of the trench segment 202e may be connected in a connection region 204c to an approximate midpoint along the trench segment 202d. A second end of the trench segment 202e may be facing the deep trench structure 178a. The trench segments 202d and 202e, and the connection region 204c, may be arranged such that the deep trench structure 178b has an approximately T-shaped top view layout. However, other top view layouts for the deep trench structure 178b are within the scope of the present disclosure.

As indicated above, FIGS. 3A-3E are provided as an example. Other examples may differ from what is described with regard to FIGS. 3A-3E.

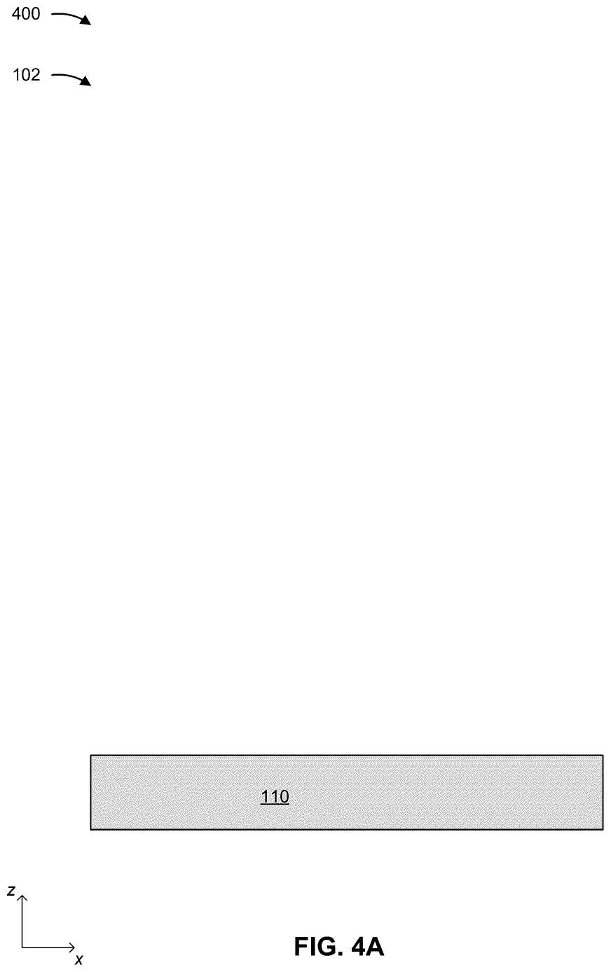

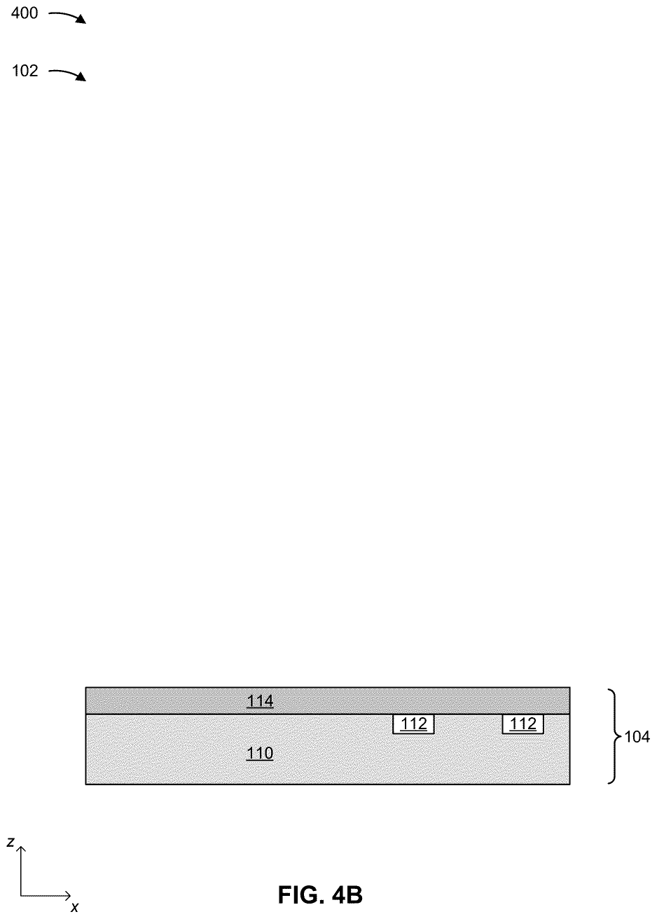

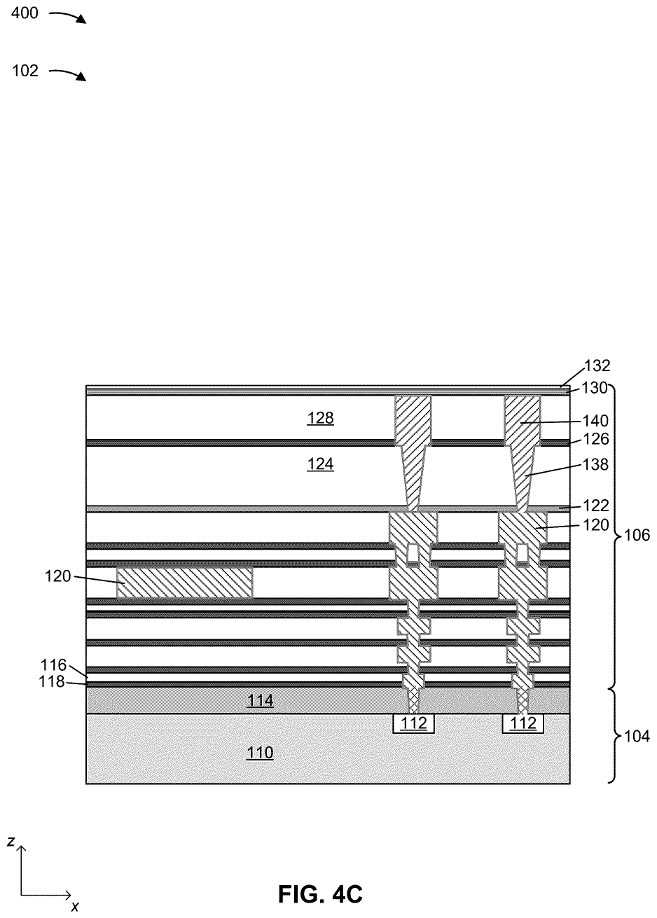

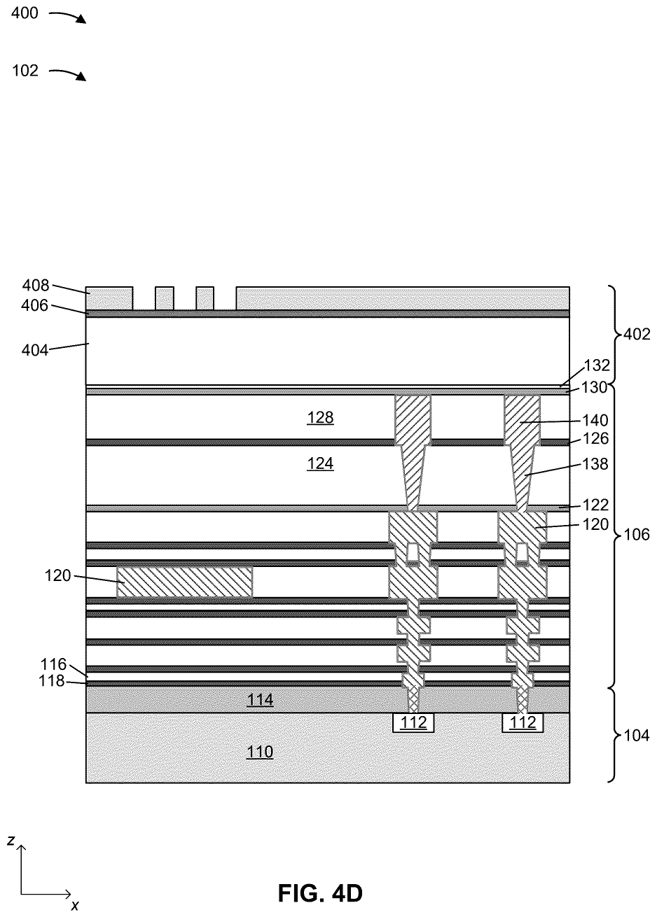

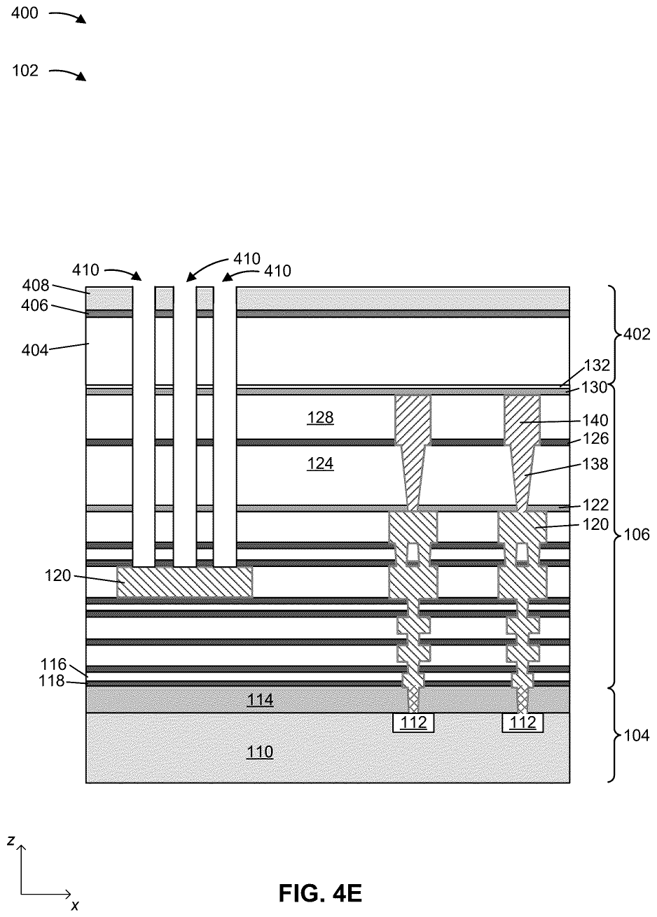

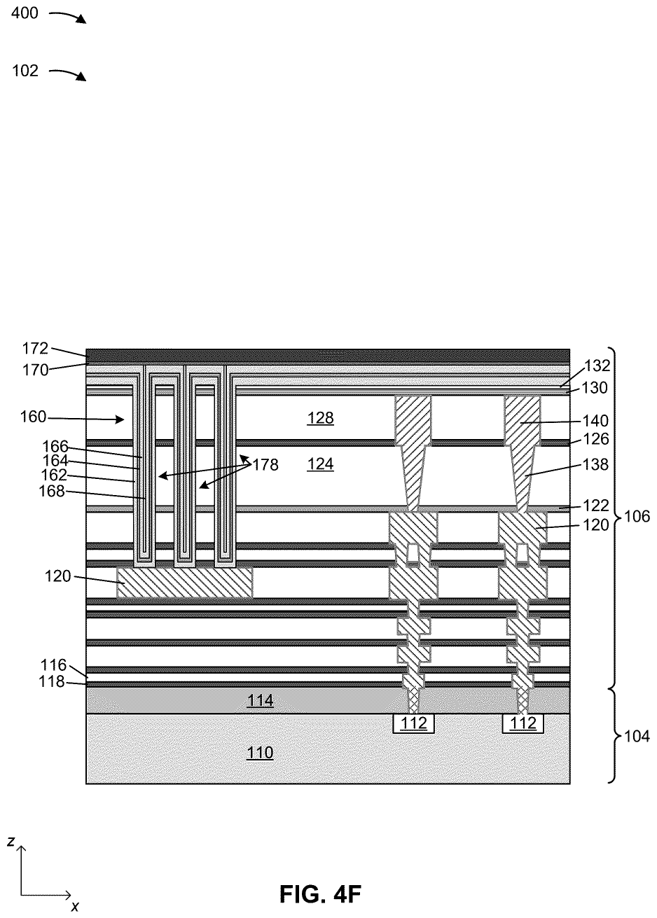

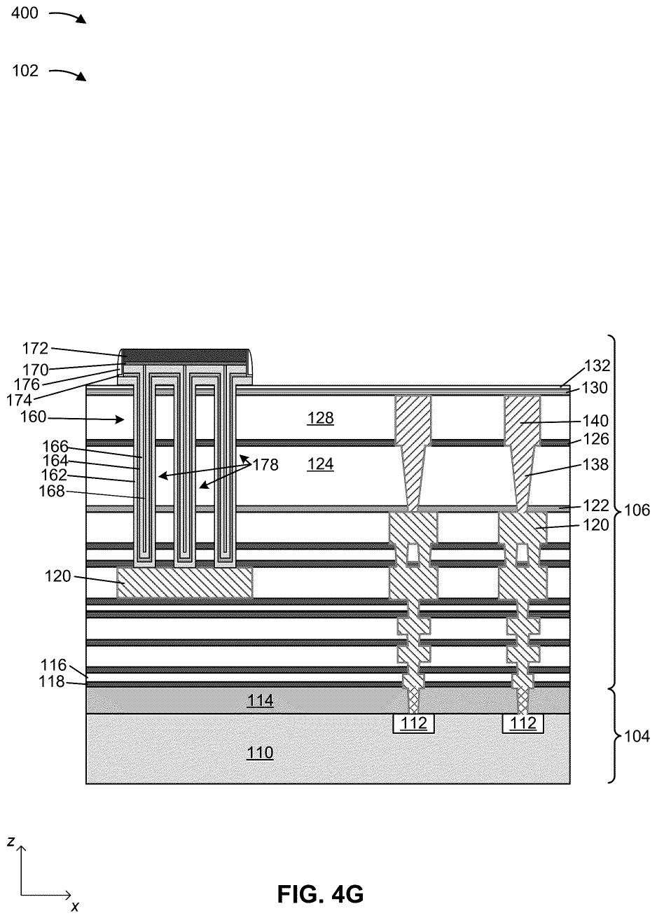

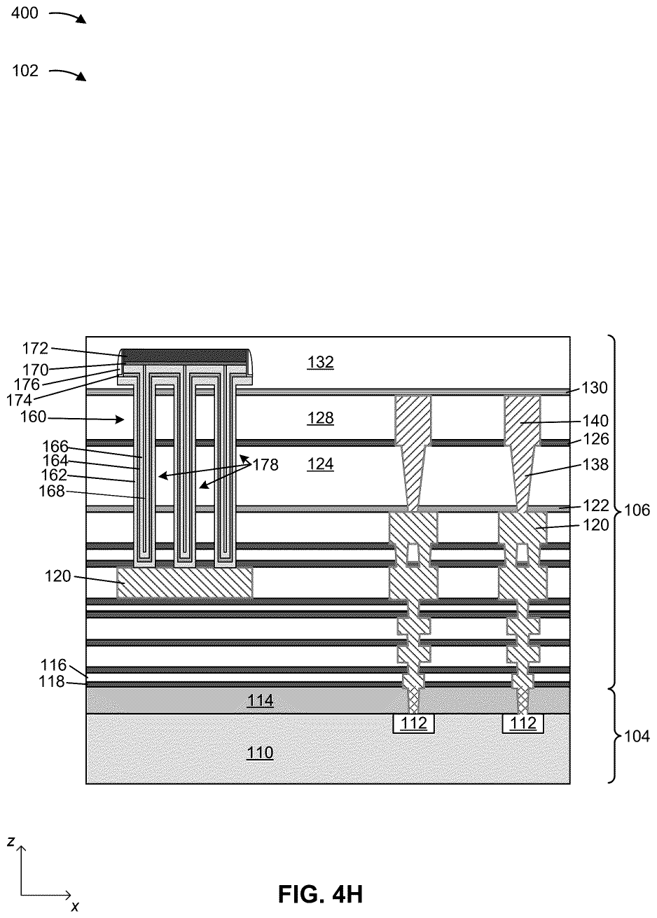

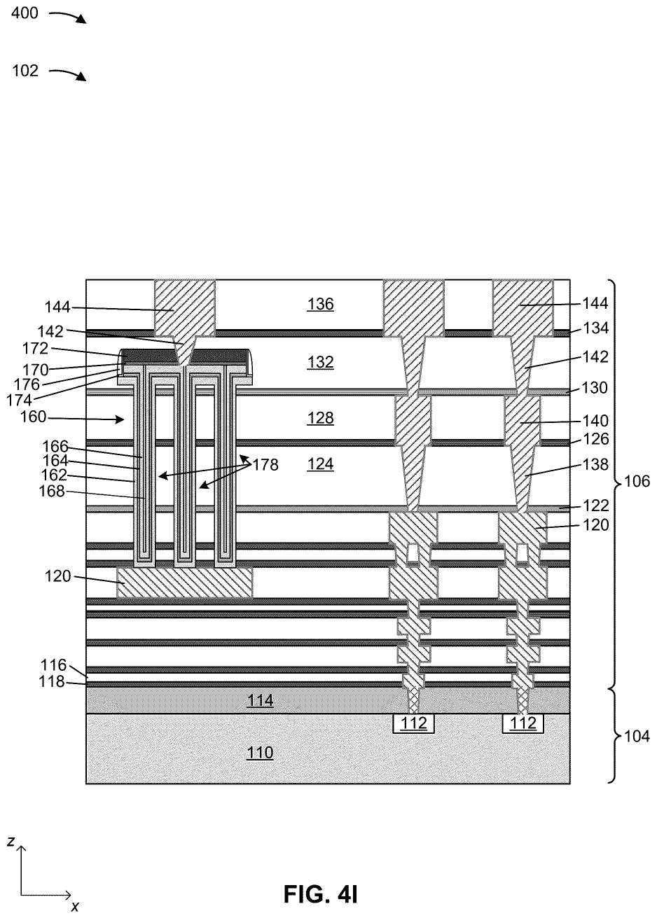

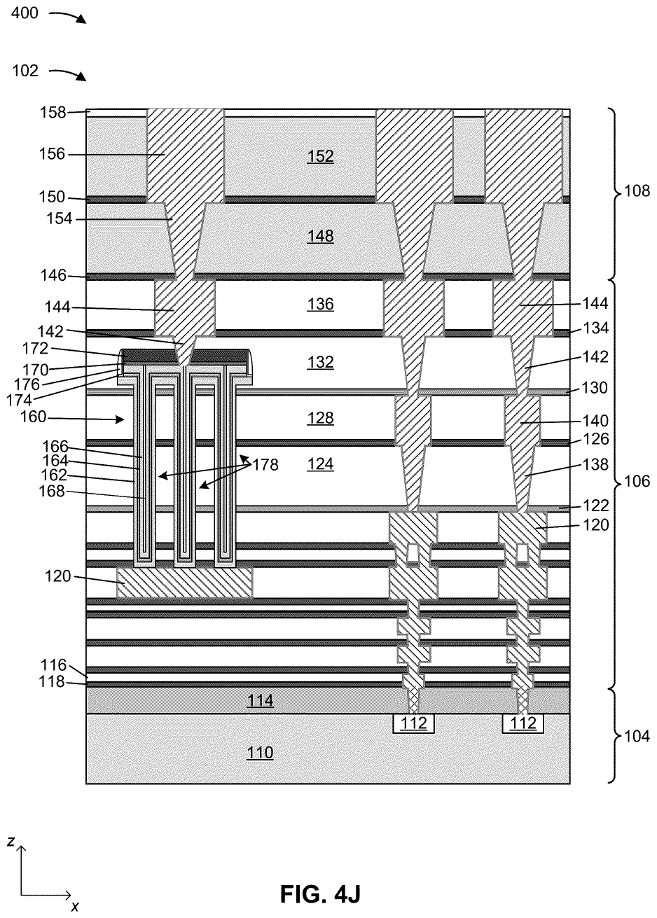

FIGS. 4A-4J are diagrams of an example implementation 400 of forming a semiconductor device 102 described herein. In particular, the example implementation 400 includes an example of forming the example implementation 100 of the semiconductor device 102 illustrated in FIG. 1. However, one or more of the semiconductor processing operations described in connection with FIGS. 4A-4J may be performed to form another example implementation of a semiconductor device 102 described herein. In some implementations, one or more of the semiconductor processing operations described in connection with FIGS. 4A-4J may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 4A, the substrate layer 110 may be provided. The substrate layer 110 may be provided in the form of a semiconductor wafer such as a silicon (Si) wafer, an SOI wafer, and/or another type of semiconductor work piece. The semiconductor device 102 may be formed on the semiconductor wafer with other semiconductor devices.

As shown in FIG. 4B, the integrated circuit devices 112 may be formed in and/or on the substrate layer 110 in the device layer 104 of the semiconductor device 102. One or more semiconductor processing tools may be used to form one or more portions of the integrated circuit devices 112. For example, an ion implantation tool may be used to dope one or more regions in the substrate layer 110 with one or more types of dopants to form well regions, implant regions, and/or other types of doped regions in the substrate layer 110 for the integrated circuit devices 112. As another example, a deposition tool may be used to perform various deposition operations to deposit layers and/or structures of the integrated circuit devices 112, and/or to deposit photoresist layers for etching the substrate layer 110 and/or portions of the deposited layers. As another example, an exposure tool may be used to expose the photoresist layers to form patterns in the photoresist layers. As another example, a developer tool may be used to develop the patterns in the photoresist layers. As another example, an etch tool may be used to etch the substrate layer 110 and/or portions of the deposited layers to form the integrated circuit devices 112. As another example, a planarization tool may be used to planarize portions of the integrated circuit devices 112. As another example, a plating tool may be used to deposit metal structures and/or layers of the integrated circuit devices 112.

As further shown in FIG. 4B, a deposition tool is used to deposit the dielectric layer 114 over and/or on the substrate layer 110 and over and/or on the integrated circuit devices 112. A deposition tool may be used to deposit the dielectric layer 114 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation, such as a chemical mechanical planarization (CMP) operation, to planarize the dielectric layer 114 after the dielectric layer 114 is deposited.

As shown in FIG. 4C, a first portion of the interconnect layer 106 of the semiconductor device 102 is formed above the dielectric layer 114. One or more deposition tools are used to deposit alternating layers of ILD layers 116 and ESLs 118 in the first portion of the interconnect layer 106 of the semiconductor device 102. In this way, the ILD layers 116 and ESLs 118 may be arranged in the z-direction in the semiconductor device 102. One or more deposition tools may be used to deposit each of the ILD layers 116 and each of the ESLs 118 using a PVD technique, an ALD technique, a CVD technique, an oxidation technique, and/or another suitable deposition technique. In some implementations, a planarization tool may be used to planarize the ILD layers 116 and/or the ESLs 118 after the ILD layers 116 and/or the ESLs 118 are deposited.

Prior to formation of the interconnect layer 106, contacts of the integrated circuit devices 112 may be formed through the dielectric layer 114. The contacts may be formed in recesses in the dielectric layer 114. In some implementations, a pattern in a photoresist layer is used to etch the dielectric layer 114 to form the recesses. In these implementations, a deposition tool may be used to form the photoresist layer on the dielectric layer 114. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 114 based on a pattern to form the recesses.

The contacts may be formed in the recesses. In some implementations, a contact (e.g., a gate contact) is formed on a gate structure of an integrated circuit device 112. In some implementations, a contact (e.g., a source/drain contact) is formed on a source/drain region of an integrated circuit device 112. A deposition tool may be used to deposit the material of the contacts in the recesses using a CVD technique, a PVD technique, an ALD technique, an electroplating technique, and/or another suitable deposition technique. The material of the contacts may be deposited in one or more deposition operations. In some implementations, a seed layer is first deposited, and the material of the contacts is deposited on the seed layer. In some implementations, a planarization tool is used to perform a planarization operation (e.g., a CMP operation) to planarize the contacts after the contacts are deposited such that the tops of the contacts are approximately co-planar with the top of the dielectric layer 114.

As further shown in FIG. 4C, a deposition tool, an exposure tool, a developer tool, an etch tool, a planarization tool, a plating tool, and/or another semiconductor processing tool may be used to perform various operations to form the conductive structures 120 in the first portion of the interconnect layer 106 of the semiconductor device 102. In some implementations, the first portion of the interconnect layer 106 may be formed in a plurality of layers. For example, an ILD layer 116 and an ESL 118 may be formed (e.g., using one or more deposition tools and/or one or more planarization tools), recesses may be formed in and/or through the ILD layer 116 and the ESL 118 (e.g., using an exposure tool, a developer tool, and/or an etch tool), and a first layer (e.g., the M0 layer) of conductive structures 120 (e.g., of metallization structures) may be formed in the ILD layer 116 and the ESL 118 (e.g., using one or more deposition tools and/or one or more planarization tools). Another ILD layer 116 and another ESL 118 may be formed, and a second layer (e.g., the V0 layer) of conductive structures 120 (e.g., of interconnect structures) may be formed in the ILD layer 116 and the ESL 118. Additional layers of conductive structures 120 may be formed in the interconnect layer 106 a similar manner.

One or more deposition tools may be used to deposit the conductive structures 120 using a PVD technique, an ALD technique, a CVD technique, an electroplating technique (e.g., an electro-chemical plating technique), and/or another suitable deposition technique. In some implementations, a planarization tool may be used to planarize the conductive structures 120 after the conductive structures 120 are deposited.

As further shown in FIG. 4C, the ESLs 122, 126, and 130 may be formed in the interconnect layer 106, and the ILD layers 124, 128, and 132 may be formed in the interconnect layer 106. One or more deposition tools are used to deposit the ESLs 122, 126, and 130, and the ILD layers 124, 128, and 132 using a PVD technique, an ALD technique, a CVD technique, an oxidation technique, and/or another suitable deposition technique. In some implementations, a planarization tool may be used to planarize the ESLs 122, 126, 130, and the ILD layers 124, 128, 132.

As further shown in FIG. 4C, a deposition tool, an exposure tool, a developer tool, an etch tool, a planarization tool, a plating tool, and/or another semiconductor processing tool may be used to perform various operations to form the top vias 138 and the top metal layers 140 in the first portion of the interconnect layer 106 of the semiconductor device 102. In some implementations, the ESL 122 and the ILD layer 124 may be formed, recesses may be formed in and/or through the ESL 122 and the ILD layer 124 (e.g., using an exposure tool, a developer tool, and/or an etch tool), and the top vias 138 may be formed in the recesses (e.g., using one or more deposition tools and/or one or more planarization tools). In some implementations, the ESL 126 and the ILD layer 128 may be formed, recesses may be formed in and/or through the ESL 126 and the ILD layer 128 (e.g., using an exposure tool, a developer tool, and/or an etch tool), and the top metal layers 140 may be formed in the recesses (e.g., using one or more deposition tools and/or one or more planarization tools). In some implementations, the ESL 130 and the ILD layer 132 may be formed, recesses may be formed in and/or through the ESL 130 and the ILD layer 132 (e.g., using an exposure tool, a developer tool, and/or an etch tool), and the top vias 142 may be formed in the recesses (e.g., using one or more deposition tools and/or one or more planarization tools). In some implementations, the ESL 134 and the ILD layer 136 may be formed, recesses may be formed in and/or through the ESL 134 and the ILD layer 136 (e.g., using an exposure tool, a developer tool, and/or an etch tool), and the top metal layers 144 may be formed in the recesses (e.g., using one or more deposition tools and/or one or more planarization tools).

One or more deposition tools may be used to deposit the top vias 138, 142 and the top metal layers 140, 144 using a PVD technique, an ALD technique, a CVD technique, an electroplating technique (e.g., an electro-chemical plating technique), and/or another suitable deposition technique. In some implementations, a planarization tool may be used to planarize the top vias 138, 142 and the top metal layers 140, 144 after the top vias 138, 142 and the top metal layers 140, 144 are deposited.

As shown in FIG. 4D, a patterning stack 402 may be formed above the portion of the ILD layer 132. The patterning stack 402 may include a plurality of masking layers that are used to form a recess in which a capacitor structure 160 may be formed in the semiconductor device 102. The masking layers may include an advanced patterning film (APF) layer 404, a bottom anti-reflective coating (BARC) 406 on the APF layer 404, and/or a photoresist layer 408 on the BARC 406, among other examples. The masking layers of the patterning stack 402 may be selected to form the recess for the capacitor structure 160 in a highly controlled manner to achieve substantially vertical sidewalls (and thus, a high aspect ratio) for the capacitor structure 160. The APF layer 404 may include an amorphous carbon material and/or another suitable material. The BARC 406 may include silicon oxynitride (SiON), a polymer, and/or another suitable material. A deposition tool may be used to deposit the APF layer 404, the BARC 406, and/or the photoresist layer 408 using a PVD technique, a CVD technique, an ALD technique, a spin-coating technique, and/or another suitable deposition technique.

As shown in FIG. 4E, an etch tool may be used to etch through the portion of the ILD layer 132, through the ESL 130, through the ILD layer 128, through the ESL 126, through the ILD layer 124, through the ESL 122, through one or more ESLs 118, and/or through one or more ILD layers 116 to form one or more recesses 410 to an underlying conductive structure 120 in the interconnect layer 106. The recess(es) 410 may include a plurality of interconnected trenches arranged in a top view layout illustrated in one or more of FIGS. 2A and/or 3A-3E, among other example top view layouts.

In some implementations, a pattern is formed in the photoresist layer 408, and the pattern is used to form the recess(es) 410. An exposure tool may be used to expose the photoresist layer 408 to a radiation source in order to pattern the photoresist layer 408. A developer tool may be used to develop and remove portions of the photoresist layer 408 to expose the pattern. An etch tool may be used to etch the BARC 406 and/or the APF layer 404 based on the pattern to transfer the pattern to the BARC 406 and/or to the APF layer 404. An etch tool may be used to etch through the portion of the ILD layer 132, through the ESL 130, through the ILD layer 128, through the ESL 126, through the ILD layer 124, through the ESL 122, through one or more ESLs 118, and/or through one or more ILD layers 116 based on the pattern in the photoresist layer 408, in the BARC 406, and/or in the APF layer 404 to form the recess(es) 410. In some implementations, the etch operation to form the recess(es) 410 includes a dry etch operation (e.g., a plasma-based etch operation, a gas-based etch operation), a wet chemical etch operation, and/or another type of etch operation.

In some implementations, a deep reactive ion etch technique (sometimes referred to as a “BOSCH” etch technique) may be used to achieve the high aspect ratio for the recess(es) 410. A deep reactive ion etch technique is a cyclic etch technique in which a plurality of deposition and etch cycles are performed using protective liners to minimize lateral etching. For example, a deep reactive ion etch cycle may include etching the recess(es) 410 to a first depth, forming a protective liner on the sidewalls and bottom surface of the recess(es) 410, etching the protective liner to remove the protective liner from the bottom surface of the recess(es) 410, and etching the bottom of the recess(es) 410 to increase the depth of the recess(es) 410 to a second depth while the protective liner protects the sidewalls of the recess(es) 410 from lateral etching. Additional cycles may be performed to achieve a particular depth for the recesses(es) 410.

In some implementations, a photoresist removal tool may be used to remove the remaining portions of the photoresist layer 408 (e.g., using a chemical stripper, plasma ashing, and/or another technique). Moreover, an etch tool and/or a planarization tool may be used to remove the remaining portions of the BARC 406 and/or the remaining portions of the APF layer 404.

As shown in FIG. 4F, the bottom electrode layer 162, the insulator layer 164, the top electrode layer 166, and the dielectric filler 168 may be formed in the recess(es) 410. The bottom electrode layer 162 may be conformally deposited on the sidewalls and on the bottom surface (which corresponds to the top surface of the conductive structure 120 exposed through the recess(es) 410) of the recess(es) 410. The bottom electrode layer 162 may also be deposited on the top surface of the portion of the dielectric layer 148. In some implementations, a conformal CVD technique and/or an ALD technique is used to deposit the bottom electrode layer 162.

The insulator layer 164 may be deposited on the bottom electrode layer 162. Thus, the insulator layer 164 is deposited on the sidewalls and on the bottom surface (which corresponds to the top surface of the conductive structure 120 exposed through the recess(es) 410) of the recess(es) 410. The insulator layer 164 may also be deposited over the top surface of the portion of the dielectric layer 148. In some implementations, a deposition tool is used to conformally deposit the insulator layer 164 using a conformal CVD technique and/or an ALD technique.

The top electrode layer 166 may be deposited on the insulator layer 164. Thus, the top electrode layer 166 is deposited on the sidewalls and on the bottom surface (which corresponds to the top surface of the conductive structure 120 exposed through the recess(es) 410) of the recess(es) 410. The top electrode layer 166 may also be deposited over the top surface of the portion of the dielectric layer 148. In some implementations, a deposition tool is used to conformally deposit the top electrode layer 166 using a conformal CVD technique and/or an ALD technique.

The dielectric filler 168 may be deposited on the top electrode layer 166 such that the dielectric filler 168 fills the remaining area of the recess(es) 410. In some implementations, a deposition tool is used to deposit the dielectric filler 168 using a PVD technique, a CVD technique, an ALD technique, and/or another suitable deposition technique.

As further shown in FIG. 4F, the capping layers 170 and 172 may be formed above the recess(es) 410. For example, the capping layers 170 and 172 may be formed over the top surface of the ILD layer 132. A deposition tool may be used to deposit the capping layers 170 and 172 using a PVD technique, an ALD technique, a CVD technique, an oxidation technique, and/or another suitable deposition technique. In some implementations, a planarization tool may be used to perform a planarization operation (e.g., a CMP operation) to planarize the capping layers 170 and/or 172 after the capping layers 170 and/or 172 are deposited.

As shown in FIG. 4G, an etch operation may be performed to define the capping layers 170 and 172, the top electrode layer 166, and/or the insulator layer 164 of the capacitor structure 160. An etch tool may be used to etch the capping layers 170 and 172, the top electrode layer 166, and/or the insulator layer 164. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the patterned masking layers (e.g., using a chemical stripper, plasma ashing, and/or another technique).

As further shown in FIG. 4G, the sidewall spacers 174 and 176 are formed on the ends of the insulator layer 164, on the ends of the top electrode layer 166, on the ends of the capping layer 170, and/or on the ends of the capping layer 172. A deposition tool may be used to deposit the sidewall spacers 174 and 176 using a PVD technique, an ALD technique, a CVD technique, an oxidation technique, and/or another suitable deposition technique. The sidewall spacers 174 and 176 may be deposited in one or more deposition operations.

As further shown in FIG. 4G, another etch operation may be performed to trim the portions of the bottom electrode layer 162 above the top surface of the portion of the dielectric layer 148 to define the bottom electrode layer 162 of the capacitor structure. The capping layer 172 and the sidewall spacers 174 and 176 may be used as a self-aligned mask to etch the bottom electrode layer 162. In some implementations, the etch operation includes a dry etch operation (e.g., a plasma-based etch operation, a gas-based etch operation), a wet chemical etch operation, and/or another type of etch operation.

As shown in FIG. 4H, additional material of the ILD layer 132 may be formed such that the top of the capacitor structure 160 is encapsulated in the ILD layer 132. A deposition tool may be used to deposit the additional material of the ILD layer 132 using a PVD technique, an ALD technique, a CVD technique, an oxidation technique, and/or another suitable deposition technique. In some implementations, a planarization tool may be used to planarize the ILD layer 132 after the additional material of the ILD layer 132 is deposited.

As shown in FIG. 4I, the ESL 134 and the ILD layer 136 may be formed, recesses may be formed in and/or through the ESL 134 and the ILD layer 136 (e.g., using an exposure tool, a developer tool, and/or an etch tool), and the top metal layers 144 may be formed in the recesses (e.g., using one or more deposition tools and/or one or more planarization tools).

One or more deposition tools may be used to deposit the top vias 142 and the top metal layers 144 using a PVD technique, an ALD technique, a CVD technique, an electroplating technique (e.g., an electro-chemical plating technique), and/or another suitable deposition technique. In some implementations, a planarization tool may be used to planarize the top vias 142 and the top metal layers 144 after the top vias 142 and the top metal layers 144 are deposited.

As further shown in FIG. 4I, a top via 142 may be formed such that the top via 142 lands on the top electrode layer 166 of the capacitor structure 160. The top via 142 electrically connects the capacitor structure 160 to a top metal layer 144 and to other structures in the semiconductor device 102.

As shown in FIG. 4J, the ESLs 146 and 150 of the bonding layer 108, the dielectric layers 148 and 152 of the bonding layer 108, and the bonding dielectric layer 158 of the bonding layer 108 may be formed above the interconnect layer 106. Bonding vias 154 may be formed in and/or through the ESL 146 and the dielectric layer 148, and may be formed on top metal layers 144. Bonding pads 156 may be formed in and/or through the ESL 150, the dielectric layer 152, and/or the bonding dielectric layer 158, and may be formed on the bonding vias 154.

One or more deposition tools may be used to deposit the ESL 146, the dielectric layer 148, the ESL 150, the dielectric layer 152, and/or the bonding dielectric layer 158 using a PVD technique, an ALD technique, a CVD technique, an oxidation technique, and/or another suitable deposition technique. In some implementations, a planarization tool may be used to perform a planarization operation (e.g., a CMP operation) to planarize the ESL 146, the dielectric layer 148, the ESL 150, the dielectric layer 152, and/or the bonding dielectric layer 158.

In some implementations, the bonding vias 154 and the bonding pads 156 may be formed in dual damascene recesses. For example, a first etch operation may be performed to form a trench portion of the dual damascene recesses, and a second etch operation may be performed to form a via portion of the dual damascene recesses. As another example, a first etch operation may be performed to form a via portion of the dual damascene recesses, and a second etch operation may be performed to form a trench portion of the dual damascene recesses. The bonding vias 154 may be formed in the via portions of the dual damascene recesses, and the bonding pads 156 may be formed in the trench portions of the dual damascene recesses.

A deposition tool may be used to deposit the bonding vias 154 and bonding pads 156 using a CVD technique, a PVD technique, an ALD technique, an electroplating technique, and/or another suitable deposition technique. The bonding vias 154 and bonding pads 156 may be deposited in one or more deposition operations. In some implementations, a seed layer is first deposited in the dual damascene recesses, and the bonding vias 154 and bonding pads 156 are deposited on the seed layer. In some implementations, a liner layer (e.g., an adhesion liner, a barrier liner) is first deposited in the dual damascene recesses, and the bonding vias 154 and bonding pads 156 are deposited on the liner layer. The liner layer may include a suitable liner material such as a tantalum nitride (TaN) and/or titanium nitride (TiN), among other examples. In some implementations, a planarization tool is used to perform a planarization operation (e.g., a CMP operation) to planarize the bonding pads 156 after the bonding vias 154 and bonding pads 156 are deposited.

As indicated above, FIGS. 4A-4J are provided as an example. Other examples may differ from what is described with regard to FIGS. 4A-4J.

FIG. 5 is a diagram of another example implementation 500 of the semiconductor device 102 described herein. As shown in FIG. 5, the example implementation 500 of the semiconductor device 102 may include a similar combination and arrangement of layers and/or structures as the example implementation 100 of the semiconductor device 102 illustrated in FIG. 1.

However, in the example implementation 500 in FIG. 5, a high aspect ratio for the capacitor structure 160 is achieved by directly connecting the top of the capacitor structure 160 to a bonding via 154 in the bonding layer 108 of the semiconductor device 102 (e.g., as opposed to connecting the top of the capacitor structure 160 to a top via 142 at the top of the interconnect layer 106, and by directly connecting the bottom of the capacitor structure 160 to a gate structure 502 (e.g., a polysilicon gate structure, a metal gate structure) of an integrated circuit device 112 in and/or on the substrate layer 110 of the semiconductor device 102. The direct connection of the top of the capacitor structure 160 to the bonding via 154, and the direction connection of the bottom of the capacitor structure 160 to a gate structure 502 of an integrated circuit device 112, enables the capacitor structure 160 to be included in and extend through a portion of the bonding layer 108, as well as in and through the interconnect layer 106 to the device layer 104. This may enable the capacitance of the capacitor structure 160 to be increased (e.g., up to 12 times the capacitance or greater than if the capacitor structure 160 only extended through the interconnect layer 106).

As shown in FIG. 5, the portion of the top electrode layer 166 at the top of the capacitor structure 160 may be in physical contact with (e.g., direct physical contact with) a bonding via 154 at the top of the capacitor structure 160. Thus, the top electrode layer 166 may be directly electrically connected to the bonding via 154 in the bonding layer 108.

The bonding via 154 connected to the top electrode layer 166 of the capacitor structure 160 may extend through the capping layers 170 and 172. In some implementations, the bonding via 154 connected to the top electrode layer 166 of the capacitor structure 160 may extend into the top electrode layer 166 such that the bottom surface of the bonding via 154 is recessed in the top electrode layer 166.

As further shown in FIG. 5, the bottom of the capacitor structure 160 (e.g., the portion of the bottom electrode layer 162 at the bottom of the capacitor structure 160) may be on and/or in contact with a gate structure 502 (e.g., a polysilicon gate structure, a metal gate structure) of an integrated circuit device 112 included in and/or on the substrate layer 110 of the semiconductor device 102. The gate structure 502, to which the capacitor structure 160 is connected, may be a gate structure of a transistor structure and/or another type of integrated circuit structure. In some implementations, the gate structure 502, to which the capacitor structure 160 is connected, may also be connected to one or more conductive structures 120 in the interconnect layer 106 of the semiconductor device 102. In some implementations, the gate structure 502, to which the capacitor structure 160 is connected, may have a z-direction thickness (dimension D10) that is included in a range of approximately 500 angstroms to approximately 1500 angstroms. However, other values and ranges are within the scope of the present disclosure.

As further shown in FIG. 5, the gate structures 502 may be electrically isolated by shallow trench isolation (STI) regions 504 that extend into the substrate layer 110. The STI region 504 may include one or more dielectric materials such as silicon oxide (SiOₓ such as SiO₂), silicon nitride (SiₓN_{y}), and/or another suitable dielectric material.

One or more integrated circuit devices 112 in the device layer 104 of the semiconductor device 102 may include doped region(s) 506 under the gate structure(s) 502 of the semiconductor device 102. In some implementations, a doped region 506 may include a p-type doped region (e.g., a region of the substrate layer 110 doped with one or more p-type dopants such as boron (B) or gallium (Ga), among other examples). In some implementations, a doped region 506 may include an n-type doped region (e.g., a region of the substrate layer 110 doped with one or more n-type dopants such as arsenic (As) or phosphorus (P), among other examples). In some implementations, a doped region 506 may be omitted from an integrated circuit device 112, and the region of the substrate layer 110 under the gate structure 502 of the integrated circuit device 112 may be undoped semiconductor material (e.g., undoped silicon (Si)).

The deep trench structure 178 of the capacitor structure 160 may extend into and/or through the ILD layers 116, the ESLs 118, the ESL 122, the ILD layer 124, the ESL 126, the ILD layer 128, the ESL 130, and/or the ILD layer 132, the ESL 134, the ILD layer 136, the ESL 146, and/or the dielectric layer 148. The deep trench structure 178 of the capacitor structure 160 may have a top view layout according to one or more of the example implementations of top view layouts illustrated in FIGS. 2A and/or 3A-3E, among other examples. In some implementations, the deep trench structure 178 of the capacitor structure 160 has a z-direction depth or height (dimension D11) that is included in a range of approximately 4 microns to approximately 6 microns. However, other values and ranges are within the scope of the present disclosure. In some implementations, the capacitor structure 160 may include greater than one deep trench structure 178. For example, the capacitor structure 160 may include two deep trench structures 178, three deep trench structures 178, and/or another quantity of deep trench structures 178.

As indicated above, FIG. 5 is provided as an example. Other examples may differ from what is described with regard to FIG. 5.

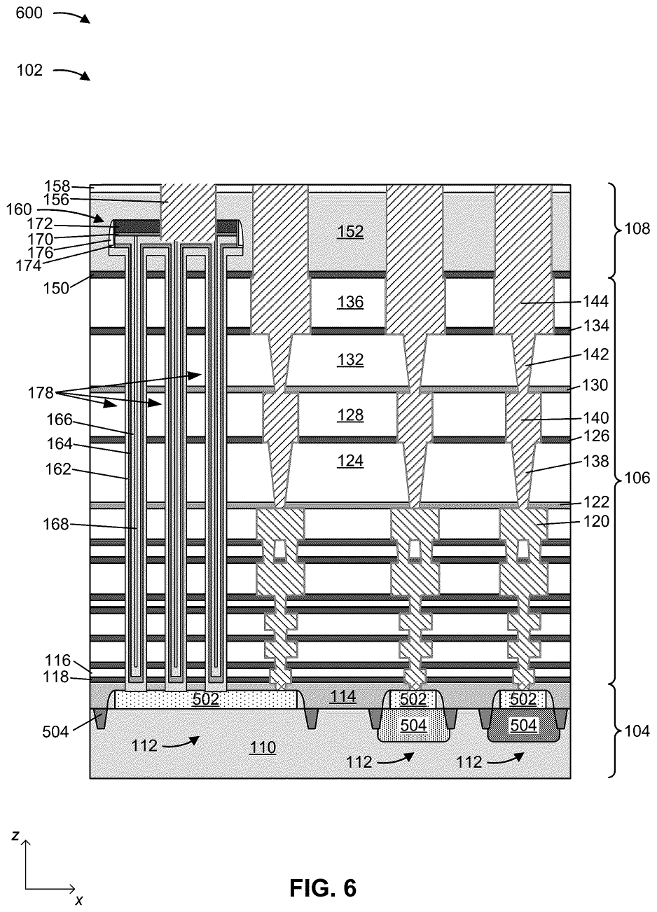

FIG. 6 is a diagram of another example implementation 600 of the semiconductor device 102 described herein. As shown in FIG. 6, the example implementation 600 of the semiconductor device 102 may include a similar combination and arrangement of layers and/or structures as the example implementation 500 of the semiconductor device 102 illustrated in FIG. 5. However, in the example implementation 600 in FIG. 6, the ESL 146, the dielectric layer 148, and the bonding vias 154 are omitted from the semiconductor device 102. Instead, the bonding pads 156 are directly connected (e.g., physically and/or electrically) to the top metal layer 144, as well as directly connected (e.g., physically and/or electrically) to the top electrode layer 166 of the capacitor structure 160.

As shown in FIG. 6, the ESL 150 may be included on the ILD layer 136, the dielectric layer 152 may be included on the ESL 150, and the bonding dielectric layer 158 may be included on the dielectric layer 152. The top of the capacitor structure 160 may be included in the dielectric layer 152. In some implementations, a vertical (z-direction) thickness of the dielectric layer 152 in the example implementation 200 of the semiconductor device 102 may be included in a range of approximately 6800 angstroms to approximately 16600 angstroms. However, other values and ranges are within the scope of the present disclosure.

The bonding pad 156 connected to the top electrode layer 166 of the capacitor structure 160 may extend through the capping layers 170 and 172. In some implementations, the bonding pad 156 connected to the top electrode layer 166 of the capacitor structure 160 may extend into the top electrode layer 166 such that the bottom surface of the bonding pad 156 is recessed in the top electrode layer 166.

As further shown in FIG. 6, the bottom of the capacitor structure 160 (e.g., the portion of the bottom electrode layer 162 at the bottom of the capacitor structure 160) may be on and/or in contact with a gate structure 502 (e.g., a polysilicon gate structure, a metal gate structure) of an integrated circuit device 112 included in and/or on the substrate layer 110 of the semiconductor device 102.

The deep trench structure 178 of the capacitor structure 160 may extend into and/or through the ILD layers 116, the ESLs 118, the ESL 122, the ILD layer 124, the ESL 126, the ILD layer 128, the ESL 130, and/or the ILD layer 132, the ESL 134, the ILD layer 136, the ESL 150, and/or the dielectric layer 152. The deep trench structure 178 of the capacitor structure 160 may have a top view layout according to one or more of the example implementations of top view layouts illustrated in FIGS. 2A and/or 3A-3E, among other examples. In some implementations, the capacitor structure 160 may include greater than one deep trench structure 178. For example, the capacitor structure 160 may include two deep trench structures 178, three deep trench structures 178, and/or another quantity of deep trench structures 178.

As indicated above, FIG. 6 is provided as an example. Other examples may differ from what is described with regard to FIG. 6.

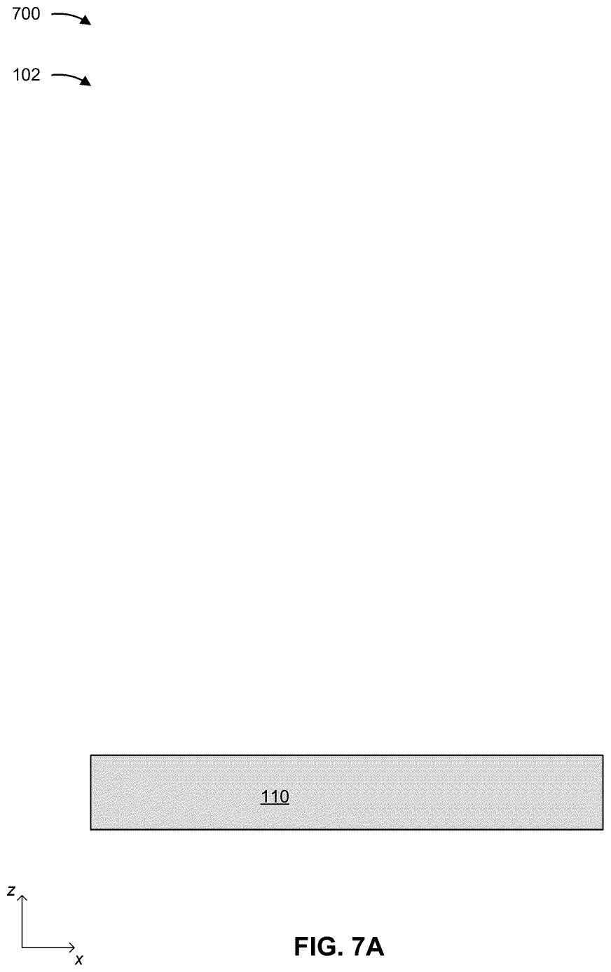

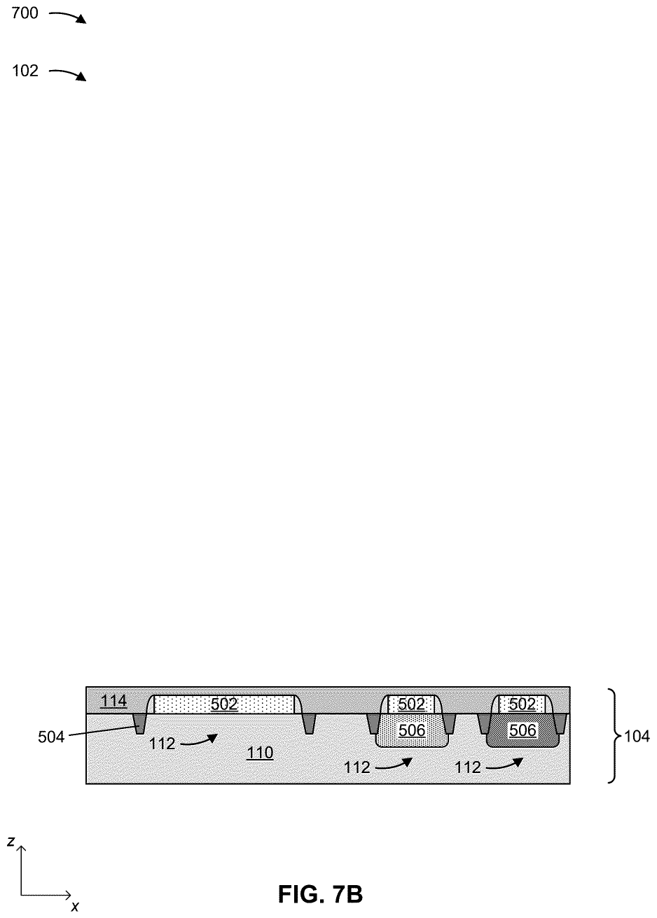

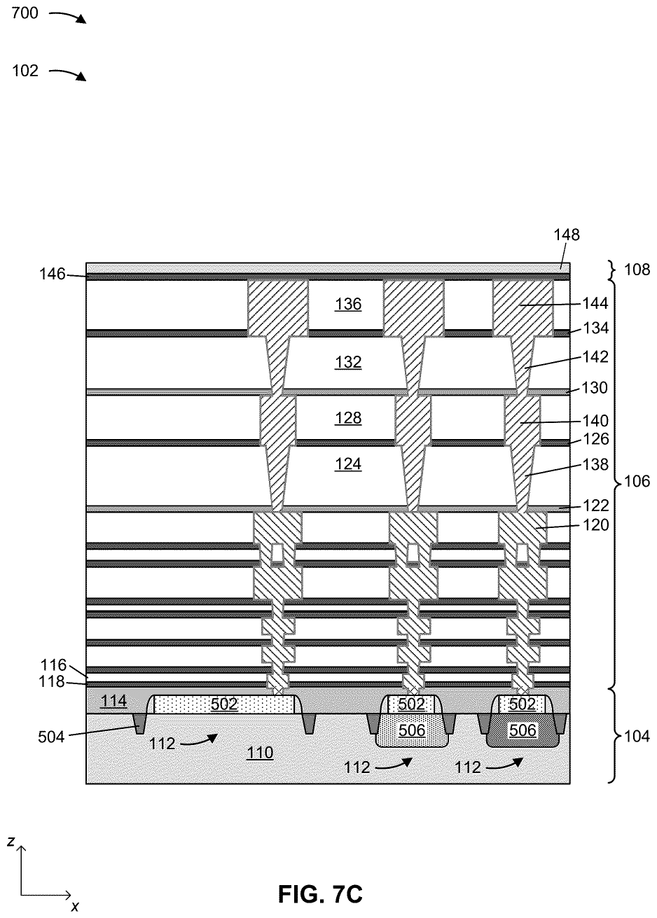

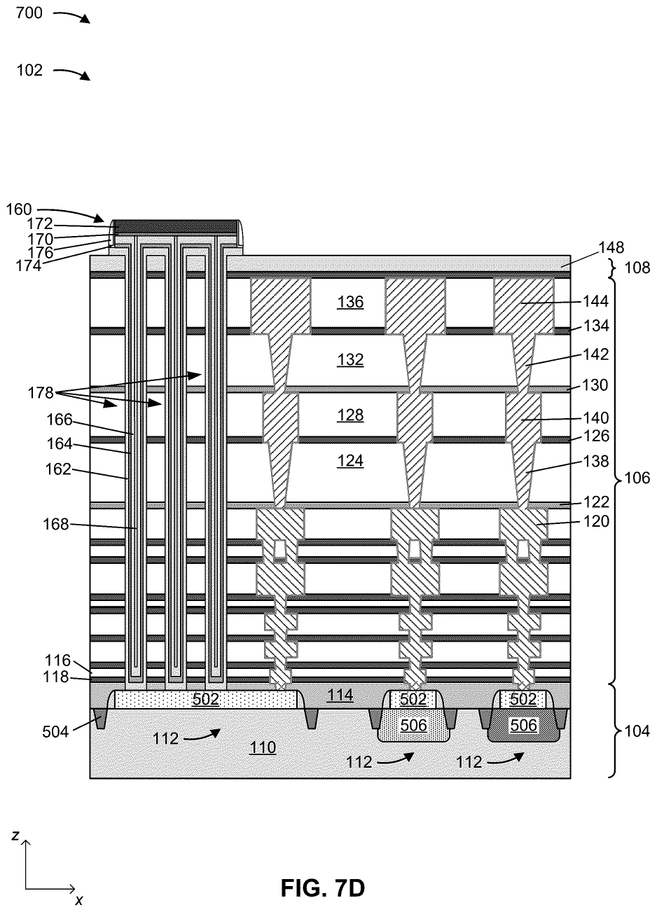

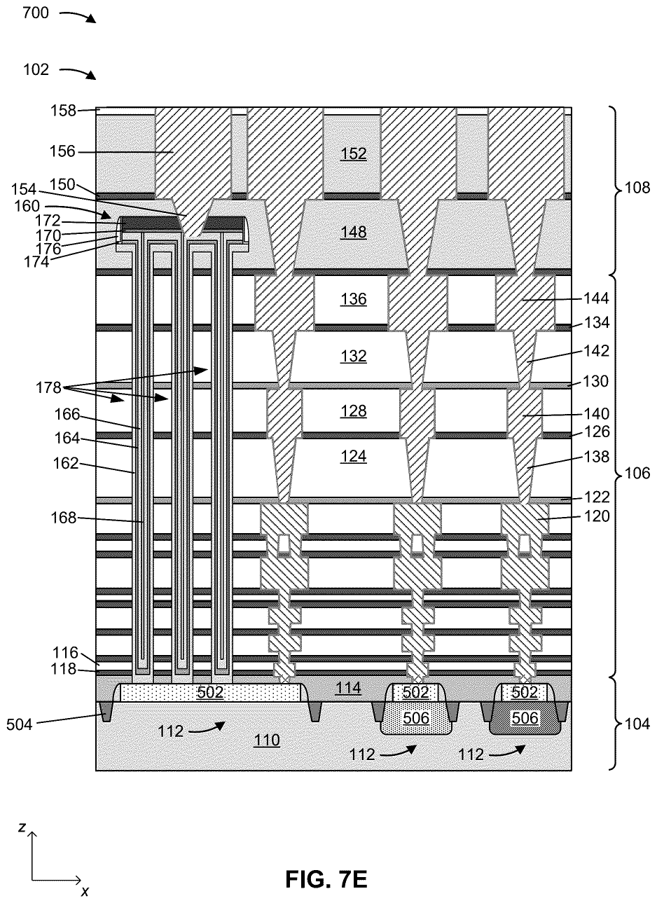

FIGS. 7A-7E are diagrams of an example implementation 700 of forming a semiconductor device 102 described herein. In particular, the example implementation 700 includes an example of forming the example implementation 500 of the semiconductor device 102 illustrated in FIG. 5. However, one or more of the semiconductor processing operations described in connection with FIGS. 7A-7E may be performed to form another example implementation of a semiconductor device 102 described herein. In some implementations, one or more of the semiconductor processing operations described in connection with FIGS. 7A-7E may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 7A, the substrate layer 110 may be provided. The substrate layer 110 may be provided in the form of a semiconductor wafer such as a silicon (Si) wafer, an SOI wafer, and/or another type of semiconductor work piece. The semiconductor device 102 may be formed on the semiconductor wafer with other semiconductor devices.

As shown in FIG. 7B, the STI regions 504 and the integrated circuit devices 112 may be formed in and/or on the substrate layer 110 in the device layer 104 of the semiconductor device 102. To form the STI regions 504, recesses may be formed in the substrate layer 110, and the STI regions 504 may be formed in the recesses. In some implementations, a pattern in a photoresist layer is used to etch the substrate layer 110 to form the recesses. In these implementations, a deposition tool may be used to form the photoresist layer on the substrate layer 110 (e.g., using a spin-coating technique and/or another suitable deposition technique). An exposure tool may be used to expose the photoresist layer to a radiation source in order to pattern the photoresist layer. A developer tool may be used to develop and remove portions of the photoresist layer to expose the pattern. An etch tool may be used to etch the substrate layer 110 based on the pattern to form the recesses. A deposition tool may be used to deposit the STI regions 504 in the recesses using a PVD technique, an ALD technique, a CVD technique, an oxidation technique and/or another suitable deposition technique. In some implementations, a planarization tool may be used to perform a planarization operation (e.g., a CMP operation) to planarize the STI regions 504 after the STI regions 504 are deposited.

One or more semiconductor processing tools may be used to form one or more portions of the integrated circuit devices 112. For example, an ion implantation tool may be used to dope one or more regions in the substrate layer 110 with one or more types of dopants to form the doped regions 506 in the substrate layer 110 for the integrated circuit devices 112. As another example, a deposition tool may be used to perform various deposition operations to deposit the gate structures 502 of the integrated circuit devices 112. As another example, an exposure tool and an etch tool may be used to pattern and etch the gate structures 502.

As further shown in FIG. 7B, a deposition tool is used to deposit the dielectric layer 114 over and/or on the substrate layer 110 and over and/or on the integrated circuit devices 112. A deposition tool may be used to deposit the dielectric layer 114 using a PVD technique, an ALD technique, a CVD technique, an oxidation technique, and/or another suitable deposition technique. In some implementations, a planarization tool may be used to perform a planarization operation, such as a CMP operation, to planarize the dielectric layer 114 after the dielectric layer 114 is deposited.

As shown in FIG. 7C, the interconnect layer 106 may be formed above the device layer 104 of the semiconductor device 102. The ILD layers 116, 124, 128, 132, 136; the ESLs 118, 122, 126, 130, 134; the conductive structures 120, the top vias 138, 142; and/or the top metal layers 140, 144 of the interconnect layer 106 may be formed in a similar manner as described in connection with FIGS. 4A-4J. As further shown in FIG. 7C, the ESL 146 and a portion of the dielectric layer 148 of the bonding layer 108 may be formed above the interconnect layer 106.

As shown in FIG. 7D, a capacitor structure 160 may be formed in and/or through the bonding layer 108, and in and/or through the interconnect layer 106. For example, a recess may be formed through the ILD layers 116, 124, 128, 132, 136; the ESLs 118, 122, 126, 130, 134, 146; and the dielectric layer 148. The bottom electrode layer 162, the insulator layer 164, the top electrode layer 166, and the dielectric filler 168 may be formed in the recess. The recess may be formed down to a gate structure 502 of an integrated circuit device 112 in the device layer 104. The bottom electrode layer 162 of the capacitor structure 160 may be formed in the recess such that a portion of the bottom electrode layer 162 at the bottom of the recess lands on the gate structure 502 exposed in the recess.

As shown in FIG. 7E, an additional portion of the dielectric layer 148 may be formed over the top of the capacitor structure 160 and over the first portion of the dielectric layer 148. The top of the capacitor structure 160 may be encapsulated in the dielectric layer 148. The ESL 150 of the bonding layer 108 may be formed on the dielectric layer 148, the dielectric layer 152 of the bonding layer 108 may be formed on the ESL 150, and the bonding dielectric layer 158 of the bonding layer 108 may be formed on the dielectric layer 152. A deposition tool may be used to deposit the additional portion of the dielectric layer 148, the ESL 150, the dielectric layer 152, and/or the bonding dielectric layer 158 using a PVD technique, an ALD technique, a CVD technique, an oxidation technique, and/or another suitable deposition technique. The additional portion of the dielectric layer 148, the ESL 150, the dielectric layer 152, and/or the bonding dielectric layer 158 may be deposited in one or more deposition operations. In some implementations, a planarization tool may be used to perform a planarization operation (e.g., a CMP operation) to planarize the dielectric layer 148, the ESL 150, the dielectric layer 152, and/or the bonding dielectric layer 158.

As further shown in FIG. 7E, the bonding vias 154 are formed in and/or through the dielectric layer 148 and the ESL 146, and the bonding pads 156 are formed on the bonding vias 154 such that the bonding pads 156 extend through the ESL 150, the dielectric layer 152, and/or the bonding dielectric layer 158. A bonding via 154 may be formed in a via portion of a recess such that the bonding via 154 lands on the top electrode layer 166 of the capacitor structure 160. In some implementations, the bonding via 154 is formed such that the bonding via 154 is recessed in a portion of the top electrode layer 166. In other words, the bottom surface of the bonding via 154 may be located below the top surface of the top electrode layer 166.

A deposition tool may be used to deposit the bonding vias 154 and bonding pads 156 using a CVD technique, a PVD technique, an ALD technique, an electroplating technique, and/or another suitable deposition technique. The bonding vias 154 and bonding pads 156 may be deposited in one or more deposition operations. In some implementations, a seed layer is first deposited, and the bonding vias 154 and bonding pads 156 are deposited on the seed layer. In some implementations, a liner layer (e.g., an adhesion liner, a barrier liner) is first deposited, and the bonding vias 154 and bonding pads 156 are deposited on the liner layer. The liner layer may include a suitable liner material such as a tantalum nitride (TaN) and/or titanium nitride (TiN), among other examples. In some implementations, a planarization tool is used to perform a planarization operation (e.g., a CMP operation) to planarize the bonding pads 156 after the bonding vias 154 and bonding pads 156 are deposited.

As indicated above, FIGS. 7A-7E are provided as an example. Other examples may differ from what is described with regard to FIGS. 7A-7E.

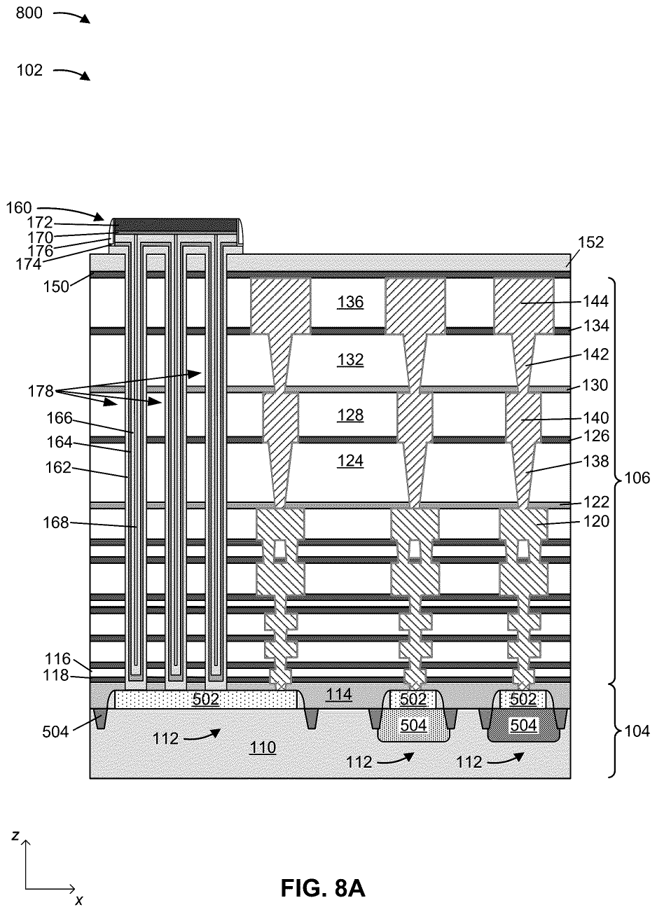

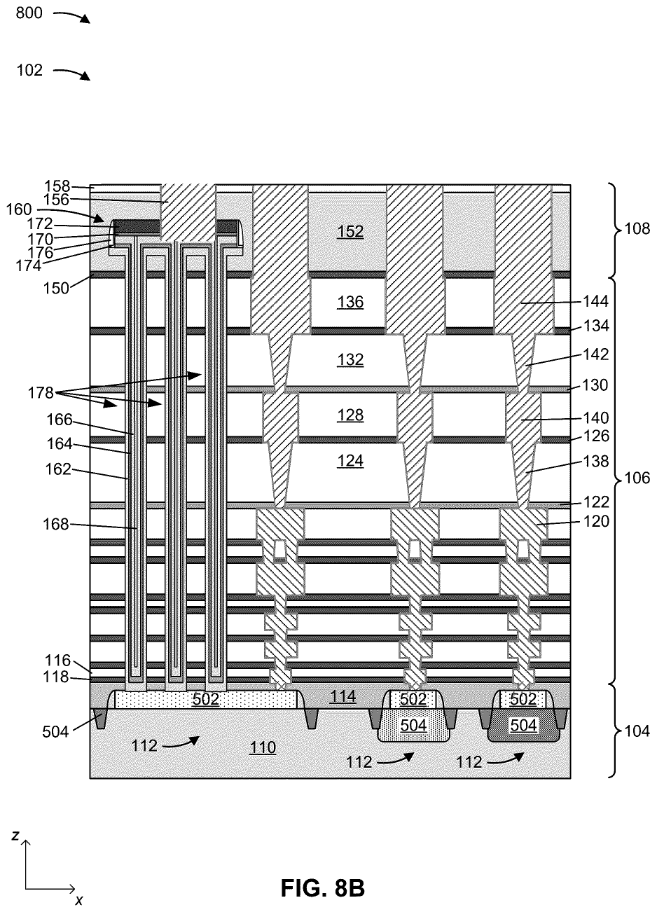

FIGS. 8A and 8B are diagrams of an example implementation 800 of forming a semiconductor device 102 described herein. In particular, the example implementation 800 includes an example of forming the example implementation 600 of the semiconductor device 102 illustrated in FIG. 6. However, one or more of the semiconductor processing operations described in connection with FIGS. 8A and 8B may be performed to form another example implementation of a semiconductor device 102 described herein. In some implementations, one or more of the semiconductor processing operations described in connection with FIGS. 8A and 8B may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 8A, one or more of the semiconductor processing operations described in connection with FIGS. 7A-7D may be performed to form the device layer 104, the interconnect layer 106, and the capacitor structure 160. However, in the example implementation 800, formation of the ESL 146 and formation of the dielectric layer 148 are omitted. Instead, the ESL 150 is formed on the ILD layer 136, the dielectric layer 152 is formed on the ESL 150, and the bonding dielectric layer 158 is formed on the dielectric layer 152. The recess for the capacitor structure 160 may be formed through a portion of the dielectric layer 152 and through the ESL 150 instead of through a portion of the dielectric layer 148 and instead of through the ESL 146.

As shown in FIG. 8B, a bonding pad 156 is formed on the top electrode layer 166 of the capacitor structure 160. The bonding pad 156 may be formed in a recessed portion of the top electrode layer 166. In other words, the bottom surface of the bonding pad 156 may be located below the top surface of the top electrode layer 166. Bonding pads 156 may also be formed in the recesses 504 such that the bonding pads 156 land on the top metal layers 144. In some implementations, a planarization tool may be used to planarize the bonding pads 156 after the bonding pads 156 are formed in the recesses.

As indicated above, FIGS. 8A and 8B are provided as an example. Other examples may differ from what is described with regard to FIGS. 8A and 8B.

FIGS. 9A and 9B are diagrams of an example implementation 900 of a semiconductor package 902 described herein. As shown in a cross-section view of the semiconductor package 902 in FIG. 9A, the semiconductor package 902 is a three-dimensional (3D) structure that includes a semiconductor device 102a (e.g., a first semiconductor die) and a semiconductor device 102b (e.g., a second semiconductor die) that are directly bonded together at a bonding interface 904 such that the semiconductor device 102a and the semiconductor device 102b are stacked and vertically arranged in the semiconductor package 902. The semiconductor device 102a and the semiconductor device 102b may each include a similar combination and arrangement of layers and/or structures as the example implementation 500 of the semiconductor device 102 illustrated in FIG. 5, and may be formed by similar semiconductor processing operations and/or techniques as described in connection with FIGS. 7A-7E.

At the bonding interface 904, the semiconductor device 102a and the semiconductor device 102b may be bonded together with a combination of metal-to-metal bonds and dielectric-to-dielectric bonds. For example, the bonding pads 156 of the semiconductor device 102a may be bonded to the bonding pads 156 of the semiconductor device 120b in metal-to-metal bonds at the bonding interface 904. As another example, the bonding dielectric layer 158 of the semiconductor device 102a may be bonded to the bonding dielectric layer 158 of the semiconductor device 102b in a dielectric-to-dielectric bond at the bonding interface 904.

In some implementations, an offset may occur at the bonding interface 904 between a bonding pad 156 of the semiconductor device 102a and a bonding pad 156 of the semiconductor device 102b. Thus, offset regions 906 may occur on one or more sides of the bond between the bonding pads 156 of the semiconductor devices 102a and 102b. A offset region 906 may include a portion of the bonding surface of the bonding pad 156 of the semiconductor device 102a that is in contact with the bonding dielectric layer 158 of the semiconductor device 102b. Another offset region 906 may include a portion of the bonding surface of the bonding pad 156 of the semiconductor device 102b that is in contact with the bonding dielectric layer 158 of the semiconductor device 102a. In other words, the bonding pads 156 are laterally offset such that the edges of the bonding pads 156 of the semiconductor devices 102a and 102b that are bonded together may be offset.

In some implementations, the semiconductor package 902 is an image sensor device (e.g., a 3D complementary metal-oxide-semiconductor (CMOS) image sensor (CIS) device). Thus, the semiconductor device 102a may include an ASIC die of the image sensor device, and the semiconductor device 102b may include an image sensor die of the image sensor device. Thus, the semiconductor device 102b may include a plurality of pixel sensors 908 in the substrate layer 110 of the semiconductor device 102b. The pixel sensors 908 may be configured to absorb photons of incident light and to convert the photons to a photocurrent for generation of images and/or video. The semiconductor device 102a and/or the semiconductor device 102b may include one or more capacitor structures 160 that are configured to store charge for the pixel sensors 908 to increase the full well conversion (FWC) of the pixel sensors 908 and/or to enable global shutter functionality in the semiconductor device 102b.

For example, the semiconductor device 102a may include a capacitor structure 160 that is directly connected to a bonding via 154 in the bonding layer 108 of the semiconductor device 102a. The capacitor structure 160 may be electrically connected to a bonding pad 156 of the semiconductor device 102b through the bonding via 154 and through a bonding pad 156 of the semiconductor device 102a that is physically connected with the bonding via 154 and the bonding pad 156 of the semiconductor device 102b. This enables the capacitor structure 160 included in the semiconductor device 102a to be electrically connected to a pixel sensor 908 included in the semiconductor device 102b. Moreover, the bottom of the capacitor structure 160 may be directly connected to a gate structure 502 in the substrate layer 110 of the semiconductor device 102a.

Additionally and/or alternatively, the semiconductor device 102b may include a capacitor structure 160 that is directly connected to a bonding via 154 in the bonding layer 108 of the semiconductor device 102b. The capacitor structure 160 may be electrically connected to a bonding pad 156 of the semiconductor device 102a through the bonding via 154 and through a bonding pad 156 of the semiconductor device 102b that is physically connected with the bonding via 154 and the bonding pad 156 of the semiconductor device 102a. Moreover, the bottom of the capacitor structure 160 may be directly connected to a gate structure 502 in the substrate layer 110 of the semiconductor device 102b.

FIG. 9B illustrates a top view of the semiconductor package 902, and illustrates an example of a pixel sensor array 910 that includes a plurality of the pixel sensors 908. As shown in FIG. 9B, the pixel sensors 908 may be arranged in a grid in the pixel sensor array 910. As further shown in FIG. 9B, a periphery region 912 may laterally surround the pixel sensor array 910. The periphery region 912 may include other functional structures of the semiconductor package 902, such as black level correction (BLC) structures and/or other pixel circuit components (e.g., source-follower transistors, row-select transistors).

As further shown in FIG. 9B, capacitor structures 160 included in the semiconductor device 102a and/or in the semiconductor device 102b may be located under the pixel sensors 908 of the pixel sensor array 910. The location of a portion of the cross-section shown in FIG. 9A is indicated by the line B-B in FIG. 9B. The bonding pads 156 and the bonding vias 154 of the semiconductor devices 102a and 102b provide “in-pixel” connections between the pixel sensors 908 of the pixel sensor array 910 in that the capacitor structures 160 on the semiconductor device 102a may be positioned under, and electrically connected to, a pixel sensor 908 through bonding vias 154 and bonding pads 156 of the semiconductor devices 102a and 102b under the pixel sensor 908.

As indicated above, FIGS. 9A and 9B are provided as an example. Other examples may differ from what is described with regard to FIGS. 9A and 9B.

FIGS. 10A and 10B are diagrams of an example implementation 1000 of a semiconductor package 1002 described herein. As shown in a cross-section view of the semiconductor package 1002 in FIG. 10A, the semiconductor package 1002 is a 3D structure that includes a semiconductor device 102a (e.g., a first semiconductor die) and a semiconductor device 102b (e.g., a second semiconductor die) that are directly bonded together at a bonding interface 1004 such that the semiconductor device 102a and the semiconductor device 102b are stacked and vertically arranged in the semiconductor package 1002. The semiconductor device 102a and the semiconductor device 102b may each include a similar combination and arrangement of layers and/or structures as the example implementation 600 of the semiconductor device 102 illustrated in FIG. 6, and may be formed by similar semiconductor processing operations and/or techniques as described in connection with FIGS. 7A-7E and/or 8A and 8B.

At the bonding interface 1004, the semiconductor device 102a and the semiconductor device 102b may be bonded together with a combination of metal-to-metal bonds and dielectric-to-dielectric bonds. For example, the bonding pads 156 of the semiconductor device 102a may be bonded to the bonding pads 156 of the semiconductor device 120b in metal-to-metal bonds at the bonding interface 1004. As another example, the bonding dielectric layer 158 of the semiconductor device 102a may be bonded to the bonding dielectric layer 158 of the semiconductor device 102b in a dielectric-to-dielectric bond at the bonding interface 1004.

In some implementations, an offset may occur at the bonding interface 1004 between a bonding pad 156 of the semiconductor device 102a and a bonding pad 156 of the semiconductor device 102b. Thus, offset regions 1006 may occur on one or more sides of the bond between the bonding pads 156 of the semiconductor devices 102a and 102b. An offset region 1006 may include a portion of the bonding surface of the bonding pad 156 of the semiconductor device 102a that is in contact with the bonding dielectric layer 158 of the semiconductor device 102b. Another offset region 1006 may include a portion of the bonding surface of the bonding pad 156 of the semiconductor device 102b that is in contact with the bonding dielectric layer 158 of the semiconductor device 102a. In other words, the bonding pads 156 are laterally offset such that the edges of the bonding pads 156 of the semiconductor devices 102a and 102b that are bonded together may be offset.

In some implementations, the semiconductor package 1002 is an image sensor device (e.g., a 3D CIS device). Thus, the semiconductor device 102a may include an ASIC die of the image sensor device, and the semiconductor device 102b may include an image sensor die of the image sensor device. Thus, the semiconductor device 102b may include a plurality of pixel sensors (not shown) in the substrate layer 110 of the semiconductor device 102b. The pixel sensors may be configured to absorb photons of incident light and to convert the photons to a photocurrent for generation of images and/or video. The semiconductor device 102a and/or the semiconductor device 102b may include one or more capacitor structures 160 that are configured to store charge for the pixel sensors 1008 to increase the FWC of the pixel sensors and/or to enable global shutter functionality in the semiconductor device 102b.

For example, the semiconductor device 102a may include a capacitor structure 160 that is directly connected to a bonding pad 156 in the bonding layer 108 of the semiconductor device 102a. The capacitor structure 160 may be electrically connected to a bonding pad 156 of the semiconductor device 102b through the bonding pad 156 of the semiconductor device 102a (which is bonded to the bonding pad 156 on the semiconductor device 102b). This enables the capacitor structure 160 included in the semiconductor device 102a to be electrically connected to a pixel sensor 1008 included in the semiconductor device 102b. Moreover, the bottom of the capacitor structure 160 may be directly connected to a gate structure 502 in the substrate layer 110 of the semiconductor device 102a.

Additionally and/or alternatively, the semiconductor device 102b may include a capacitor structure 160 that is directly connected to a bonding pad 156 in the bonding layer 108 of the semiconductor device 102b. The capacitor structure 160 may be electrically connected to a bonding pad 156 of the semiconductor device 102a through the bonding pad 156 of the semiconductor device 102b (which is bonded to the bonding pad 156 on the semiconductor device 102a). Moreover, the bottom of the capacitor structure 160 may be directly connected to a gate structure 502 in the substrate layer 110 of the semiconductor device 102b.

FIG. 10B illustrates a top view of the semiconductor package 1002, and illustrates an example of pixel sensors 1008 in a pixel sensor array 1010. As shown in FIG. 10B, the pixel sensors 1008 may be arranged in a grid in the pixel sensor array 1010. As further shown in FIG. 10B, a periphery region 1012 may laterally surround the pixel sensor array 1010. The periphery region 1012 may include other functional structures of the semiconductor package 1002, such as BLC structures and/or other pixel circuit components (e.g., source-follower transistors, row-select transistors).

As further shown in FIG. 10B, capacitor structures 160 included in the semiconductor device 102a and/or in the semiconductor device 102b may be located around the pixel sensor array 1010. For example, capacitor structures 160 may be located in the periphery region 1012, which may correspond to a die edge or die perimeter of the semiconductor device 102a and/or of the semiconductor device 102b. The location of a portion of the cross-section shown in FIG. 10A is indicated by the line C-C in FIG. 10B. The bonding pads 156 around the perimeters of the semiconductor devices 102a and 102b provide connections between the pixel sensors 1008 of the pixel sensor array 1010 and the capacitor structures 160 on the semiconductor device 102a.

As indicated above, FIGS. 10A and 10B are provided as an example. Other examples may differ from what is described with regard to FIGS. 10A and 10B.

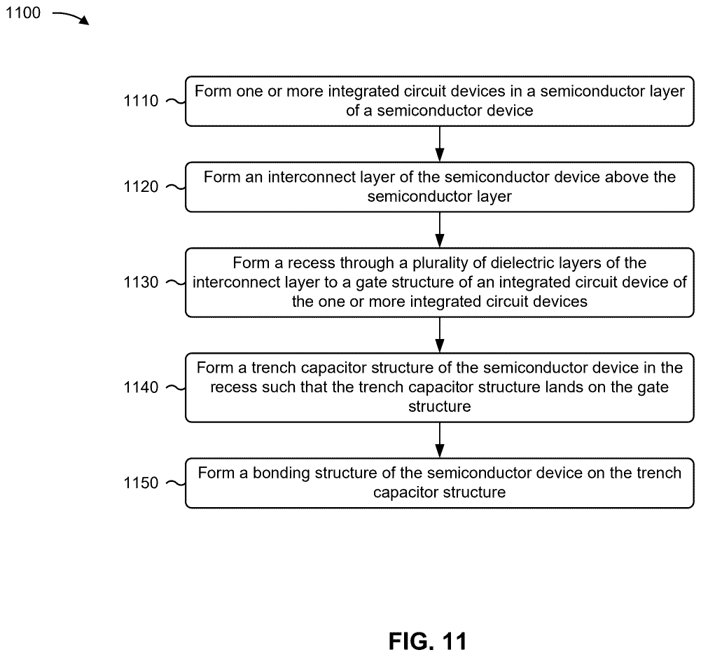

FIG. 11 is a flowchart of an example process 1100 associated with forming a semiconductor device described herein. In some implementations, one or more process blocks of FIG. 11 are performed using one or more semiconductor processing tools, such as a deposition tool, an exposure tool, a developer tool, an etch tool, a planarization tool, an ion implantation tool, an annealing tool, a wafer/die transport tool, a bonding tool, and/or another type of semiconductor processing tool.

As shown in FIG. 11, process 1100 may include forming one or more integrated circuit devices in a semiconductor layer of a semiconductor device (block 1110). For example, one or more semiconductor processing tools may be used to form one or more integrated circuit devices (e.g., one or more integrated circuit devices 112) in a semiconductor layer (e.g., a substrate layer 110) of a semiconductor device (e.g., a semiconductor device 102), as described herein.

As further shown in FIG. 11, process 1100 may include forming an interconnect layer of the semiconductor device above the semiconductor layer (block 1120). For example, one or more semiconductor processing tools may be used to form an interconnect layer (e.g., an interconnect layer 106) of the semiconductor device above the semiconductor layer, as described herein.

As further shown in FIG. 11, process 1100 may include forming a recess through a plurality of dielectric layers of the interconnect layer to a gate structure (502) of an integrated circuit device of the one or more integrated circuit devices (block 1130). For example, one or more semiconductor processing tools may be used to form a recess through a plurality of dielectric layers (e.g., one or more ILD layers 116, one or more ESLs 118, an ESL 122, an ILD layer 124, an ESL 126, an ILD layer 128, an ESL 130, an ILD layer 132, an ESL 134, an ILD layer 136) of the interconnect layer to a gate structure (e.g., a gate structure 502) of an integrated circuit device of the one or more integrated circuit devices, as described herein.

As further shown in FIG. 11, process 1100 may include forming a trench capacitor structure of the semiconductor device in the recess such that the trench capacitor structure lands on the gate structure (block 1140). For example, one or more semiconductor processing tools may be used to form a trench capacitor structure (e.g., a capacitor structure 160) of the semiconductor device in the recess such that the trench capacitor structure lands on the gate structure, as described herein.

As further shown in FIG. 11, process 1100 may include forming a bonding structure of the semiconductor device on the trench capacitor structure (block 1150). For example, one or more semiconductor processing tools may be used to form a bonding structure (e.g., a bonding via 154, a bonding pad 156) of the semiconductor device on the trench capacitor structure, as described herein.

Process 1100 may include additional implementations, such as any single implementation or any combination of implementations described below and/or in connection with one or more other processes described elsewhere herein.

In a first implementation, forming the trench capacitor structure includes forming a plurality of interconnected trench segments (e.g., trench segments 202a-202h) that are interconnected in a top view of the trench capacitor structure.

In a second implementation, alone or in combination with the first implementation, process 1100 includes bonding the semiconductor device to another semiconductor device (e.g., bonding a semiconductor device 102a and a semiconductor device 102b) such that the bonding structure is directly bonded to another bonding structure (e.g., another bonding via 154, another bonding pad 156) of the other semiconductor device.

In a third implementation, alone or in combination with one or more of the first and second implementations, the bonding structure and the other bonding structure are offset.

In a fourth implementation, alone or in combination with one or more of the first through third implementations, forming the bonding structure includes forming a bonding via (e.g., a bonding via 154) on a top electrode layer (e.g., a top electrode layer 166) of the trench capacitor structure, where the process 1100 further includes forming a bonding pad (e.g., a bonding pad 156) on the bonding via.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, a trench capacitor structure (e.g., a DTC structure) is formed in a semiconductor device to have a deep trench structure that includes a plurality of interconnected trench segments in a top view of the trench capacitor structure. The interconnected trench segments provide a greater amount of surface area along the sidewalls for the electrode layers and insulator layer of the trench capacitor structure, thereby increasing the capacitance of the trench capacitor structure. The interconnected trench segments may be included within a perimeter of the trench capacitor structure so that a compact lateral footprint for the trench capacitor structure may be achieved. Additionally and/or alternatively, the vertical size of the trench capacitor structure (and thus, the capacitance of the trench capacitor structure) may be increased by extending the deep trench structure of the trench capacitor structure fully between bonding structures of the semiconductor device and an underlying device layer of the semiconductor device. The bottom of the trench capacitor structure may be electrically connected to a gate structure of an integrated circuit device in the device layer.

As described in greater detail above, some implementations described herein provide a semiconductor device. The semiconductor device includes a semiconductor layer. The semiconductor device includes one or more integrated circuit devices at least one of in or on the semiconductor layer. The semiconductor device includes an interconnect layer above the semiconductor layer. The semiconductor device includes a capacitor structure vertically extending through the interconnect layer. The capacitor structure includes a top electrode layer, and an insulator layer between the bottom electrode layer and the top electrode layer. The bottom electrode layer, the top electrode layer, and the insulator layer extend conform to a cross-sectional profile of a deep trench. In a top view of the deep trench structure, the deep trench comprises a plurality of interconnected trench segments.

As described in greater detail above, some implementations described herein provide a semiconductor device. The semiconductor device includes a semiconductor layer. The semiconductor device includes one or more integrated circuit devices at least one of in or on the semiconductor layer. The semiconductor device includes an interconnect layer above the semiconductor layer. The semiconductor device includes one or more conductive structures in the interconnect layer. The semiconductor device includes one or more bonding structures above the interconnect layer. The semiconductor device includes a trench capacitor structure vertically extending through the interconnect layer, where a top of the trench capacitor structure is coupled to a bonding structure of the one or more bonding structures, and where a bottom of the trench capacitor structure is coupled to a gate structure of the one or more integrated circuit devices.

As described in greater detail above, some implementations described herein provide a method. The method includes forming one or more integrated circuit devices in a semiconductor layer of a semiconductor device. The method includes forming an interconnect layer of the semiconductor device above the semiconductor layer. The method includes forming a recess through a plurality of dielectric layers of the interconnect layer to a gate structure of an integrated circuit device of the one or more integrated circuit devices. The method includes forming a trench capacitor structure of the semiconductor device in the recess such that the trench capacitor structure lands on the gate structure. The method includes forming a bonding structure of the semiconductor device on the trench capacitor structure.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor layer;
one or more integrated circuit devices on the semiconductor layer;
an interconnect layer above the semiconductor layer; and
a trench capacitor structure, vertically extending through the interconnect layer, comprising:
a bottom electrode layer;
a top electrode layer; and
an insulator layer between the bottom electrode layer and the top electrode layer,
wherein the bottom electrode layer, the top electrode layer, and the insulator layer conform to a cross-sectional profile of a deep trench, and
wherein, in a top view of the capacitor structure, the capacitor structure comprises a plurality of interconnected trench segments.

2. The semiconductor device of claim 1, wherein the plurality of interconnected trench segments comprise:
a first trench segment;
a second trench segment;
a third trench segment; and
a fourth trench segment,
wherein a first end of the first trench segment and a first end of the third trench segment are connected at a first connection region,
wherein a second end of the first trench segment and a first end of the fourth trench segment are connected at a second connection region,
wherein a first end of the second trench segment and a second end of the third trench segment are connected at a third connection region, and
wherein a second end of the second trench segment and a second end of the fourth trench segment are connected at a fourth connection region.

3. The semiconductor device of claim 2, wherein the plurality of interconnected trench segments comprise:
a fifth trench segment; and
a sixth trench segment,
wherein a first end of the fifth trench segment is connected to the first end of the first trench segment and the first end of the third trench segment in the first connection region,
wherein a second end of the fifth trench segment is connected to the second end of the second trench segment and the second end of the fourth trench segment in the fourth connection region,
wherein a first end of the sixth trench segment is connected to the first end of the second trench segment and the second end of the third trench segment in the third connection region, and
wherein a second end of the sixth trench segment is connected to the second end of the first trench segment and the first end of the fourth trench segment in the second connection region.

4. The semiconductor device of claim 3, wherein the first trench, the second trench, the third trench, and the fourth trench are arranged in an approximate hollow rectangle layout in the top view of the trench capacitor structure;
wherein the fifth trench segment extends diagonally between two corners of the approximate hollow rectangle layout; and
wherein the sixth trench segment extends diagonally between two other corners of the approximate hollow rectangle layout.

5. The semiconductor device of claim 2, wherein the plurality of interconnected trench segments comprise:
a fifth trench segment; and
a sixth trench segment,
wherein a first end of the fifth trench segment is connected to the first trench segment in a fifth connection region between the first end of the first trench segment and the second end of the first trench segment,
wherein a second end of the fifth trench segment is connected to the second trench segment in a sixth connection region between the first end of the second trench segment and the second end of the second trench segment,
wherein a first end of the sixth trench segment is connected to the third trench segment in a seventh connection region between the first end of the third trench segment and the second end of the third trench segment, and
wherein a second end of the sixth trench segment is connected to the fourth trench segment in an eighth connection region between the first end of the fourth trench segment and the second end of the fourth trench segment.

6. The semiconductor device of claim 5, wherein the fifth trench segment and the sixth trench segment intersect in a ninth connection region.

7. The semiconductor device of claim 2, wherein the plurality of interconnected trench segments comprise:
a fifth trench segment; and
a sixth trench segment,
wherein a first end of the fifth trench segment is connected to the first trench segment in a fifth connection region between the first end of the first trench segment and the second end of the first trench segment,
wherein a second end of the fifth trench segment is connected to the second trench segment in a sixth connection region between the first end of the second trench segment and the second end of the second trench segment,
wherein a first end of the sixth trench segment is connected to the first trench segment in a seventh connection region between the first end of the first trench segment and the second end of the first trench segment,
wherein a second end of the sixth trench segment is connected to the second trench segment in an eighth connection region between the first end of the second trench segment and the second end of the second trench segment.

8. The semiconductor device of claim 1, wherein the trench capacitor structure further comprises:
another deep trench vertically extending through the interconnect layer,
wherein the other deep trench is spaced apart from the deep trench,
wherein the bottom electrode layer, the top electrode layer, and the insulator layer extend into the other deep trench, and
wherein, in a top view of the other deep trench, the other deep trench comprises another plurality of interconnected trench segments.

9. A semiconductor device, comprising:
a semiconductor layer;
one or more integrated circuit devices on the semiconductor layer;
an interconnect layer above the semiconductor layer;
one or more conductive structures in the interconnect layer;
one or more bonding structures above the interconnect layer; and
a trench capacitor structure vertically extending through the interconnect layer,
wherein a top of the trench capacitor structure is coupled to a bonding structure of the one or more bonding structures, and
wherein a bottom of the trench capacitor structure is coupled to a gate structure of the one or more integrated circuit devices.

10. The semiconductor device of claim 9, wherein the bonding structure comprises a bonding via;
wherein the one or more bonding structures further comprise a bonding pad; and
wherein the bonding pad is coupled to the bonding via.

11. The semiconductor device of claim 10, wherein a top electrode layer of the trench capacitor structure is coupled with the bonding via; and
wherein a bottom electrode layer of the trench capacitor structure is coupled with the gate structure.

12. The semiconductor device of claim 11, wherein a bottom surface of the bonding via is recessed in the top electrode layer.

13. The semiconductor device of claim 9, wherein the bonding structure comprises a bonding pad.

14. The semiconductor device of claim 13, wherein a top electrode layer of the trench capacitor structure is coupled with the bonding pad; and
wherein a bottom electrode layer of the trench capacitor structure is coupled with the gate structure.

15. The semiconductor device of claim 9, wherein a subset of the one or more conductive structures is coupled to the gate structure.

16. A method, comprising:
forming one or more integrated circuit devices in a semiconductor layer of a semiconductor device;
forming an interconnect layer of the semiconductor device above the semiconductor layer;
forming a recess through a plurality of dielectric layers of the interconnect layer to a gate structure of an integrated circuit device of the one or more integrated circuit devices;
forming a trench capacitor structure of the semiconductor device in the recess such that the trench capacitor structure lands on the gate structure; and
forming a bonding structure of the semiconductor device on the trench capacitor structure.

17. The method of claim 16, wherein forming the trench capacitor structure comprises:
forming a plurality of interconnected trench segments that are interconnected in a top view of the trench capacitor structure.

18. The method of claim 16, further comprising:
bonding the semiconductor device to another semiconductor device such that the bonding structure is directly bonded to another bonding structure of the other semiconductor device.

19. The method of claim 18, wherein the bonding structure and the other bonding structure are offset.

20. The method of claim 16, wherein forming the bonding structure comprises:
forming a bonding via on a top electrode layer of the trench capacitor structure,
wherein the method further comprises:
forming a bonding pad on the bonding via.
